(19) United States
(12) Patent Application Publication
(10) Pub. No.: US 2024/0372316 A1
(43) Pub. Date: Nov. 7, 2024

(54) LIGHT-EMITTING DEVICE

(71) Applicant: Panasonic Intellectual Property Management Co., Ltd., Osaka (JP)

(72) Inventors: YUKIO NISHIKAWA, Osaka (JP); TAKEHIRO ASAHI, Osaka (JP); YOSHIO OKAYAMA, Shiga (JP)

(21) Appl. No.: 18/779,051

(22) Filed: Jul. 21, 2024

Related U.S. Application Data
(63) Continuation of application No. PCT/JP2022/041740, filed on Nov. 9, 2022.

(30) Foreign Application Priority Data
Jan. 27, 2022 (JP) 2022-011001

(51) Int. Cl. H01S 5/02253

(52) U.S. Cl. CPC H01S 5/02253

(57) ABSTRACT

Light-emitting device (1) includes waveguide structure (5) and exterior part (4). Waveguide structure (5) includes light receiving surface (51) including incident end surface (31) and first surface (41), and radiation surface (52) including emission end surface (32) and second surface (42). A position of waveguide structure (5) with respect to light source (2) is determined to cause light (L1) to be incident on light receiving surface (51). Incident range (R) on which light (L1) is incident on light receiving surface (51) includes at least a part of incident end surface (31) and at least a part of first surface (41) such that a part of light (L1) is incident on incident end surface (31) and another part of light (L1) is incident on first surface (41), passes through exterior part (4), and is emitted from second surface (42).

### TECHNICAL FIELD

The present disclosure relates to a light-emitting device.

### BACKGROUND ART

PTL 1 discloses a laser machining device as an example of a light-emitting device. The laser machining device disclosed in PTL 1 is a device that irradiates an object to be machined with a laser beam to perform machining, and includes a laser light source that emits a laser beam of a fundamental wave, a wavelength conversion element that wavelength-converts the laser beam of the fundamental wave into a laser beam of a second harmonic and emits the laser beam of the fundamental wave and coaxially emits the laser beam of the unconverted fundamental wave together with the laser beam of the second harmonic, and an optical system that focuses and condenses the emitted laser beam of the second harmonic on the object to be machined and condenses the laser beam of the unconverted fundamental wave with a laser beam intensity at which the object to be machined is not focused and irradiates the object to be machined.

### CITATION LIST

### Patent Literature

PTL 1: Unexamined Japanese Patent Publication No. 2011-161483

### SUMMARY OF THE INVENTION

A light-emitting device according to an aspect of the present disclosure includes a light source that emits light having directionality and having a single wavelength, and a waveguide structure that includes an optical waveguide and an exterior part, the optical waveguide having an incident end surface and an emission end surface, converting a wavelength of light incident on the incident end surface, and emitting the light from the emission end surface, and the exterior part having light transparency and covering the optical waveguide to cause at least the incident end surface and the emission end surface to be exposed. The exterior part has a first surface and a second surface opposite to the first surface. The first surface is closer to the light source than the second surface is. The waveguide structure has a light receiving surface including the incident end surface and the first surface and a radiation surface including the emission end surface and the second surface. A position of the waveguide structure with respect to the light source is determined to cause the light to be incident on the light receiving surface. An incident range in which the light is incident on the light receiving surface includes at least a part of the incident end surface and at least a part of the first surface, a part of the light being incident on the incident end surface, and another part of the light being incident on the first surface, passing through an inside of the exterior part, and being emitted from the second surface.

### BRIEF DESCRIPTION OF THE DRAWINGS

FIG. 1 is a schematic side view of a configuration example of a light-emitting device of a first exemplary embodiment.

FIG. 2 is a perspective view of a configuration example of a waveguide structure of the light-emitting device of FIG. 1.

FIG. 3 is a schematic view of a light receiving surface of the waveguide structure of FIG. 2.

FIG. 4 is a schematic side view of a configuration example of a light-emitting device of a second exemplary embodiment.

FIG. 5 is a schematic side view of a configuration example of a light-emitting device of a third exemplary embodiment.

FIG. 6 is a schematic side view of a configuration example of a light-emitting device of a fourth exemplary embodiment.

FIG. 7 is a schematic side view of a configuration example of a light-emitting device of a fifth exemplary embodiment.

FIG. 8 is a schematic side view of a configuration example of a light-emitting device of a sixth exemplary embodiment.

FIG. 9 is a perspective view of a configuration example of a waveguide structure of the light-emitting device of FIG. 8.

FIG. 10 is a schematic view of a light receiving surface of the waveguide structure of FIG. 9.

FIG. 11 is a schematic side view of a configuration example of a light-emitting device of Modification 1.

FIG. 12 is a perspective view of a configuration example of a waveguide structure of the light-emitting device of FIG. 11.

FIG. 13 is a perspective view of a configuration example of a waveguide structure of a light-emitting device of Modification 2.

FIG. 14 is a perspective view of a configuration example of a waveguide structure of a light-emitting device of Modification 3.

FIG. 15 is a perspective view of a configuration example of a waveguide structure of a light-emitting device of Modification 4.

FIG. 16 is a perspective view of a configuration example of a waveguide structure of a light-emitting device of Modification 5.

### DESCRIPTION OF EMBODIMENT

In the laser machining device disclosed in PTL 1, the object to be machined is irradiated with the laser beam of the unconverted fundamental wave and the laser beam of the second harmonic from the wavelength conversion element. However, in the configuration described in PTL 1, an output ratio between and sectional shapes of the laser beam of the fundamental wave and the laser beam of the second harmonic depend on a wavelength conversion behavior in the wavelength conversion element. It is difficult to set the output ratio between and the sectional shapes of the laser beam of the fundamental wave and the laser beam of the second harmonic by the wavelength conversion behavior in the wavelength conversion element, and a range that can be set by the wavelength conversion behavior is limited. Thus, it is desirable that the output ratio between and the sectional shapes of the laser beam of the fundamental wave and the laser beam of the second harmonic can be easily and freely set in consideration of the purpose of use and the like thereof.

The present disclosure provides a light-emitting device capable of emitting a plurality of light rays having different wavelengths from light having a single wavelength at desired output ratios and sectional shape.

Hereinafter, exemplary embodiments will be described in detail with reference to the drawings as appropriate. However, descriptions more in detail than necessary may be omitted. For example, the detailed description of already well-known matters and the redundant description of substantially identical configurations may be omitted. These omissions are intended to avoid excessive redundancy in the following description, and to facilitate understanding of those skilled in the art. Note that, the inventor(s) of the present disclosure provide the accompanying drawings and the following description to help those skilled in the art to fully understand the present disclosure and thus do not intend to limit the subject matter defined in the appended claims thereby.

A positional relationship such as up, lower, left, and right is based on a positional relationship illustrated in the drawings unless otherwise specified. Each of the drawings to be described in the following exemplary embodiments is a schematic view, and a ratio of a size and a thickness of each component in each drawing do not necessarily reflect an actual dimensional ratio. In addition, a dimensional ratio of each component is not limited to a ratio illustrated in the drawings.

In the following description, names of the components are intended to distinguish between the components and facilitate understanding of those skilled in the art, and are not intended to limit functions and the like of the components by the names of the components themselves. The function and the like of the component are not referred to by the name of the component itself, but are referred to in the description and the like regarding the component.

### 1. Exemplary Embodiments

### 1.1 First Exemplary Embodiment

### [1.1.1 Configuration]

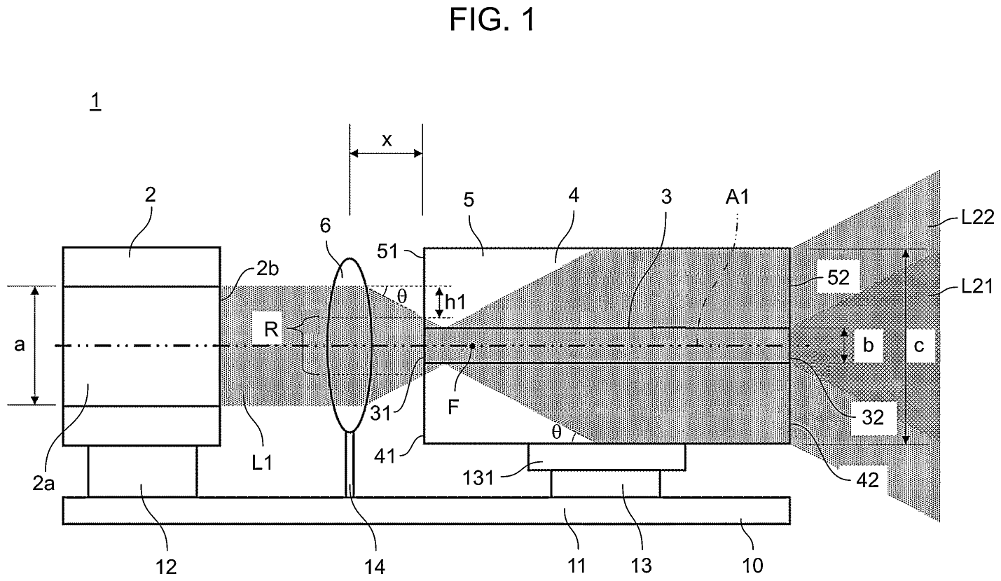

FIG. 1 is a schematic side view of a configuration example of light-emitting device 1 of a first exemplary embodiment. Light-emitting device 1 of FIG. 1 includes light source 2, waveguide structure 5, and convergence optical system 6.

Light source 2 of FIG. 1 emits light L1 having directionality and having a single wavelength. Light L1 having a single wavelength may not be light having a single wavelength in a strict sense, but may be light having a certain extent of spread around a predetermined wavelength, which is understood as light having a single wavelength as common technical knowledge. In FIG. 1, light L1 travels along optical axis A1. Light source 2 is a laser, for example, a semiconductor laser. Light L1 is a laser beam. Light source 2 includes, for example, active layer 2a. One end surface of active layer 2a of light source 2 is emission surface 2b from which light L1 is emitted. Note that, since the semiconductor laser has a lower output than a machining laser or the like, but has a small size, the semiconductor laser can be combined with a small optical system to form a small light-emitting device. A wavelength of light L1 can be appropriately set in accordance with an application of light-emitting device 1. The wavelength of light L1 may be a wavelength in a visible light region, a wavelength in an infrared region, or a wavelength in an ultraviolet region.

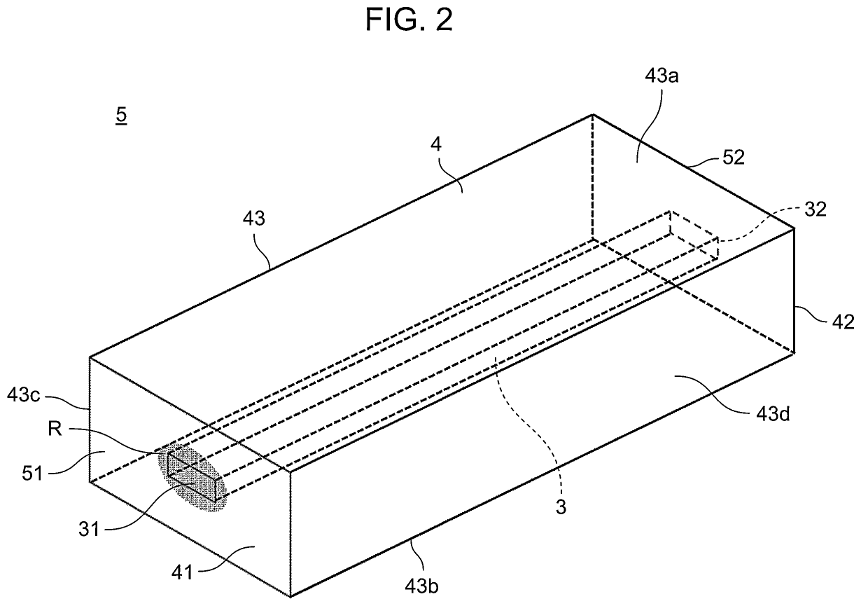

FIG. 2 is a perspective view of a configuration example of waveguide structure 5 of light-emitting device 1 of FIG. 1. Waveguide structure 5 includes optical waveguide 3 and exterior part 4.

Optical waveguide 3 is a transmission path of light L1 emitted from light source 2. Optical waveguide 3 has incident end surface 31 and emission end surface 32. Optical waveguide 3 converts the wavelength of light L1 incident from incident end surface 31 and emits light L1 from emission end surface 32.

In the present exemplary embodiment, optical waveguide 3 has a hexahedral shape. More specifically, in the present exemplary embodiment, incident end surface 31 and emission end surface 32 are both surfaces of optical waveguide 3 in a length direction (lower-left and upper-right direction in FIG. 2). Incident end surface 31 and emission end surface 32 are rectangular. Both surfaces of optical waveguide 3 in a thickness direction (up and lower direction in FIG. 2) are rectangular, and both surfaces in a width direction (upper-left and lower-right direction in FIG. 2) are rectangular.

Optical waveguide 3 is a wavelength conversion element using a non-linear optical effect. Optical waveguide 3 is made of, for example, a non-linear optical crystal. A phase matching method of the non-linear optical crystal is not particularly limited, and examples thereof include quasi-phase matching and birefringence phase matching (critical phase matching, non-critical phase matching, or the like). In the present exemplary embodiment, optical waveguide 3 is made of a non-linear optical crystal that generates a second harmonic. Examples of the non-linear optical crystal include LiB₃O₅ crystal (LBO crystal), CsLiB₆O₁₀ crystal (CLBO crystal), KTN single crystal, BNN crystal, BBO crystal, KDP crystal, KTP crystal, LN crystal, and KBBF crystal. The non-linear optical crystal is appropriately selected in accordance with a target wavelength.

Exterior part 4 covers optical waveguide 3. Exterior part 4 of FIG. 2 covers optical waveguide 3 such that incident end surface 31 and emission end surface 32 of optical waveguide 3 are exposed. In the present exemplary embodiment, exterior part 4 has a rectangular parallelepiped shape. Exterior part 4 covers optical waveguide 3 such that a length direction of exterior part 4 coincides with the length direction of optical waveguide 3. A center of optical waveguide 3 within a surface orthogonal to the length direction coincides with a center of exterior part 4 within a surface orthogonal to the length direction.

Incident end surface 31 and emission end surface 32 of optical waveguide 3 are exposed to first surface 41 and second surface 42 of exterior part 4 in the length direction, respectively. First surface 41 is a surface of exterior part 4 close to light source 2. Second surface 42 is a surface of exterior part 4 opposite to first surface 41. First surface 41 and second surface 42 are rectangular. Exterior part 4 has third surface 43a and fourth surface 43b of exterior part 4 in a thickness direction (up and lower direction in FIG. 2), and fifth surface 43c and sixth surface 43d of exterior part 4 in a width direction (upper-left and lower-right direction in FIG. 2). Third surface 43a, fourth surface 43b, fifth surface 43c, and sixth surface 43d are rectangular. Third surface 43a, fourth surface 43b, fifth surface 43c, and sixth surface 43d constitute outer surface 43 of in exterior part 4 opposite to optical waveguide 3.

In the present exemplary embodiment, exterior part 4 has light transparency. Exterior part 4 is made of a material having a light transmitting property, for example, oxide materials such as quartz glass and sapphire, inorganic materials such as a semiconductor including silicon, gallium nitride, and aluminum nitride, or polymer materials such as a polyimide-based resin and a polyamide-based resin. In the present exemplary embodiment, exterior part 4 is made of a material having a smaller refractive index than optical waveguide 3.

Waveguide structure 5 is, for example, an optical waveguide SHG element. Waveguide structure 5 of FIG. 2 has light receiving surface 51 and radiation surface 52. Light receiving surface 51 is an end surface of waveguide structure 5 close to light source 2. Radiation surface 52 is an end surface of waveguide structure 5 opposite to light receiving surface 51. A position of waveguide structure 5 with respect to light source 2 is determined such that light L1 is incident on light receiving surface 51.

Light receiving surface 51 includes incident end surface 31 of optical waveguide 3 and first surface 41 of exterior part 4. Incident end surface 31 is a central region of light receiving surface 51. First surface 41 is a region around light receiving surface 51 and surrounds incident end surface 31. In a case where there is a step between incident end surface 31 and first surface 41, one of optical waveguide 3 and exterior part 4 blocks the other on light receiving surface 51, and there is a case where the incidence of light L1 is hindered. In the present exemplary embodiment, as illustrated in FIG. 1, on light receiving surface 51, incident end surface 31 and first surface 41 are positioned on an identical plane. That is, incident end surface 31 and first surface 41 are flush with each other. Thus, utilization efficiency of light L1 can be improved.

Radiation surface 52 includes emission end surface 32 of optical waveguide 3 and second surface 42 of exterior part 4. Emission end surface 32 is a central region of radiation surface 52. Second surface 42 is a region around radiation surface 52 and surrounds emission end surface 32. When there is a step between emission end surface 32 and second surface 42, one of optical waveguide 3 and exterior part 4 blocks the other on radiation surface 52, and there is a case where the emission of light L1 is hindered. In the present exemplary embodiment, as illustrated in FIG. 1, on radiation surface 52, emission end surface 32 and second surface 42 are positioned on an identical plane. That is, emission end surface 32 and second surface 42 are flush with each other. Thus, utilization efficiency of light L1 can be improved.

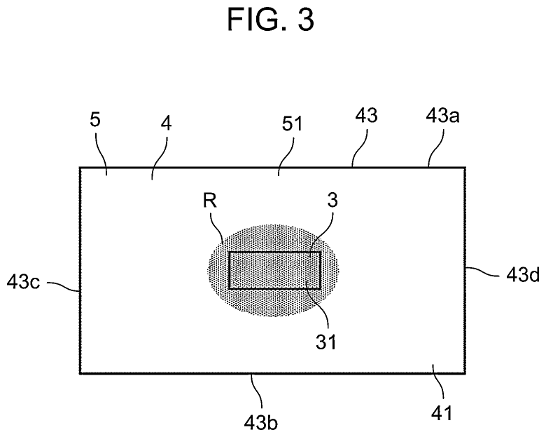

FIG. 3 is a schematic view of light receiving surface 51 of waveguide structure 5 of FIG. 2. As illustrated in FIG. 3, incident range R in which light L1 is incident on light receiving surface 51 includes at least a part of incident end surface 31 and at least a part of first surface 41 such that a part of light L1 is incident on incident end surface 31 and another part of light L1 is incident on first surface 41, passes through an inside of exterior part 4, and is emitted from second surface 42. That is, light-emitting device 1 is configured such that light L1 from light source 2 is incident on not only optical waveguide 3 but also exterior part 4. In FIG. 3, incident range R includes the entire surface of incident end surface 31.

Since incident range R includes not only incident end surface 31 but also first surface 41, exterior part 4 can emit light L1 incident on first surface 41 from second surface 42. That is, a part of light L1 is incident on incident end surface 31, passes through an inside of optical waveguide 3, and is emitted from emission end surface 32. Another part of light L1 is incident on first surface 41, passes through the inside of exterior part 4, and is emitted from second surface 42. More specifically, light L1 incident on optical waveguide 3 from incident end surface 31 of optical waveguide 3 of waveguide structure 5 propagates in the length direction of optical waveguide 3 while being reflected at a boundary surface between optical waveguide 3 and exterior part 4, and a wavelength thereof is converted in a procedure of propagation. Light L1 of which the wavelength is converted by optical waveguide 3 is emitted, as first emission light L21, from emission end surface 32 to an outside of waveguide structure 5. Light L1 incident on exterior part 4 from first surface 41 of exterior part 4 of waveguide structure 5 propagates in the length direction of exterior part 4 while being reflected by outer surface 43 of exterior part 4 opposite to optical waveguide 3. Light L1 propagating through exterior part 4 is emitted, as second emission light L22, from second surface 42 to the outside of waveguide structure 5.

As described above, light-emitting device 1 outputs first emission light L21 from optical waveguide 3 and outputs second emission light L22 having a wavelength different from a wavelength of first emission light L21 from exterior part 4 in response to the input of light L1 from light source 2. In light-emitting device 1, an output ratio between the plurality of light rays (first emission light L21 and second emission light L22) having different wavelengths can be mainly set to a desired output ratio depending on a size and a position of incident range R on light receiving surface 51. In light-emitting device 1, sectional shapes of the plurality of light rays (first emission light L21 and second emission light L22) can be mainly set to desired shapes depending on the shapes of optical waveguide 3 and exterior part 4 in waveguide structure 5 on a surface orthogonal to optical axis A1 of light L1. That is, light-emitting device 1 can emit the plurality of light rays (first emission light L21 and second emission light L22) having different wavelengths from light L1 having a single wavelength at desired output ratios and desired sectional shapes.

In light-emitting device 1, optical waveguide 3 performs wavelength conversion of light L1. For example, first emission light L21 emitted from emission end surface 32 of optical waveguide 3 corresponds to the second harmonic for light L1 from light source 2. A wavelength of first emission light L21 is ½ of the wavelength of light L1 from light source 2. On the other hand, in the present exemplary embodiment, exterior part 4 does not perform wavelength conversion of light L1. Thus, a wavelength of second emission light L22 emitted from second surface 42 of exterior part 4 is equal to the wavelength of light L1.

The wavelength of first emission light L21 and the wavelength of second emission light L22 are appropriately set in accordance with the application of light-emitting device 1.

For example, light-emitting device 1 can be applied to a machining field. In the machining field, an object can be machined by using at least one of the plurality of light rays having different wavelengths (first emission light L21 and second emission light L22) output from light-emitting device 1. One of first emission light L21 and second emission light L22 can be used for pre-processing of machining, and the other of first emission light L21 and second emission light L22 can be used for actual machining. In this case, one of first emission light L21 and second emission light L22 may be invisible light, and the other of first emission light L21 and second emission light L22 may be visible light. For example, the invisible light can be used for laser machining, and the visible light can be used as a guide indicating an irradiation position of the invisible light. As another example, in relation to absorbability of the object, machining efficiency can be improved by melting a surface of the object with the visible light and actually machining the object with the invisible light. In an application in the machining field, for example, light L1 can be set to light having a wavelength of 1064 nm (infrared light), first emission light L21 can be set to light having a wavelength of 532 nm (green light), and second emission light L22 can be set to light having a wavelength of 1064 nm (infrared light). For example, light L1 can be set to light having a wavelength of 532 nm (green light), first emission light L21 can be set to light having a wavelength of 266 nm (ultraviolet light), and second emission light L22 can be set to light having a wavelength of 532 nm (green light).

For example, light-emitting device 1 can be applied to an optical information processing field. In the optical information processing field, information can be read and transmitted by using the plurality of light rays having different wavelengths (first emission light L21 and second emission light L22) output from light-emitting device 1. First emission light L21 and second emission light L22 can be used to read information from different optical disks or to transmit different optical signals.

For example, light-emitting device 1 can be applied to an optical application measurement control field. In the optical application measurement control field, a distance to the object can be measured by a combination of the plurality of light rays having different wavelengths (first emission light L21 and second emission light L22) output from light-emitting device 1. In this case, one of first emission light L21 and second emission light L22 may be invisible light, and the other of first emission light L21 and second emission light L22 may be visible light. In this case, the distance to the object can be measured by a combination of invisible light and visible light.

As described above, light-emitting device 1 can emit the plurality of light rays (first emission light L21 and second emission light L22) having different wavelengths from light L1 having a single wavelength at desired output ratios and sectional shapes. Thus, the wavelength of first emission light L21 and the wavelength of second emission light L22 are appropriately set, and thus, light-emitting device 1 can be used for an application of irradiation with light rays having a plurality of wavelengths in various fields such as the machining field, the optical information processing field, and the optical application measurement control field.

In light-emitting device 1, in order to efficiently transmit light L1 from light source 2 without being output to the outside of waveguide structure 5, light L1 from light source 2 may be totally reflected at a boundary surface between exterior part 4 and surrounding air, that is, outer surface 43 of exterior part 4. Thus, in light-emitting device 1, light L1 is incident on light receiving surface 51 such that light L1 propagates through the inside of exterior part 4 while being totally reflected by outer surface 43.

In the present exemplary embodiment, light-emitting device 1 includes convergence optical system 6 that causes light L1 to be incident on light receiving surface 51 between light source 2 and waveguide structure 5.

Convergence optical system 6 of FIG. 1 causes light L1 to be incident on light receiving surface 51 between light source 2 and waveguide structure 5. Convergence optical system 6 includes, for example, a collimator lens and a condenser lens. The collimator lens and the condenser lens are on optical axis A1 of light L1, and light L1 from light source 2 passes through the collimator lens and the condenser lens in this order and is incident on waveguide structure 5. Light L1 becomes parallel light by the collimator lens and is converged by the condenser lens.

An angle of an outer edge of light L1 with respect to optical axis A1 within a predetermined surface passing through optical axis A1 of light L1 is θ[°], a refractive index of the exterior part is n, and a refractive index of air is n0. In this case, a critical angle on outer surface 43 of exterior part 4 is given by n×sin (90°−θ)=n×sin 90°. When refractive index n0 of the air is set to 1, in order for light L1 from light source 2 to be totally reflected by outer surface 43 of exterior part 4, θ may satisfy the following Expression (1).

$$\begin{matrix}[ Math . 1 ] & \\ θ < 90 ° - arcsin \frac{1}{n} & ( 1 )\end{matrix}$$

Accordingly, convergence optical system 6 is set such that θ satisfies Expression (1). Thus, since light L1 from light source 2 is totally reflected by outer surface 43 of exterior part 4, utilization efficiency of light L1 can be improved.

In light-emitting device 1, a positional relationship between light source 2 and waveguide structure 5 is set in consideration of the utilization efficiency of light L1. More specifically, light-emitting device 1 is configured such that all of light L1 from light source 2 is incident on light receiving surface 51 of waveguide structure 5 via convergence optical system 6. That is, incident region R is included in light receiving surface 51 without protruding from light receiving surface 51.

In light-emitting device 1 of FIG. 1, convergence optical system 6 has focal point F opposite to light source 2 with respect to light receiving surface 51 of waveguide structure 5. In FIG. 1, focal point F is virtually illustrated for easy understanding of description. That is, in light-emitting device 1 of FIG. 1, light L1 is incident on light receiving surface 51 of waveguide structure 5 before light L1 passing through convergence optical system 6 is focused. In this configuration, an interval between convergence optical system 6 and waveguide structure 5 can be narrowed. Accordingly, light-emitting device 1 can be downsized.

As illustrated in FIG. 1, a width of light L1 on emission surface 2b within a predetermined surface passing through optical axis A1 of light L1 is a, and the amount of convergence by convergence optical system 6 is h1. In a case where light L1 is incident on convergence optical system 6 without changing width a of light L1, a width of incident region R within the predetermined surface is represented by a−2×h1. Incident region R includes incident end surface 31 of optical waveguide 3 and first surface 41 of exterior part 4, but is set not to protrude from first surface 41 of exterior part 4. In this case, assuming that a width of optical waveguide 3 within the predetermined surface is b and a width of waveguide structure 5 within the predetermined surface is c, the width of incident region R satisfies the following Expression (2).

$$\begin{matrix}[ Math . 2 ] & \\ b < a - 2 \cdot h 1 < c & ( 2 )\end{matrix}$$

Assuming that a distance between a surface of convergence optical system 6 facing light receiving surface 51 and light receiving surface 51 is x, tan θ=h1/x. When h1 is removed from Expression (2) by using this relational expression, the following Expression (3) is obtained.

$$\begin{matrix}[ Math . 3 ] & \\ \frac{a - c}{2 \cdot tan θ} < x < \frac{a - b}{2 \cdot tan θ} & ( 3 )\end{matrix}$$

However, x is positive from a positional relationship between convergence optical system 6 and waveguide structure 5. Accordingly, x satisfies the following Expression (4).

$$\begin{matrix}[ Math . 4 ] & \\ 0 \leq x < \frac{a - b}{2 \cdot tan θ} & ( 4 )\end{matrix}$$

Thus, incident region R includes incident end surface 31 of optical waveguide 3 and first surface 41 of exterior part 4, but can be prevented from protruding from first surface 41 of exterior part 4, and the utilization efficiency of light L1 can be improved.

In light-emitting device 1, it is preferable that Expressions (1) and (4) are established with respect to any predetermined surface passing through optical axis A1 of light L1.

Light-emitting device 1 of FIG. 1 further includes support 10 that supports light source 2, waveguide structure 5, and convergence optical system 6. In the present exemplary embodiment, light source 2, waveguide structure 5, and convergence optical system 6 are attached to support 10, and thus, mutual positional relationships are defined.

Support 10 of FIG. 1 includes base body 11, first attachment member 12, second attachment member 13, and third attachment member 14.

First attachment member 12 is disposed on base body 11. Light source 2 is installed on a surface (upper surface in FIG. 1) of first attachment member 12 opposite to base body 11. First attachment member 12 is made of a material having high thermal conductivity, and thus, heat of light source 2 can be transmitted to base body 11 and dissipated.

Second attachment member 13 is disposed on base body 11. Waveguide structure 5 is installed on a surface (upper surface in FIG. 1) of second attachment member 13 opposite to base body 11. Second attachment member 13 is made of a material having high thermal conductivity, and thus, heat of waveguide structure 5 can be transmitted to base body 11 and dissipated. Second attachment member 13 includes movement mechanism 131 that moves waveguide structure 5 relative to light source 2. Movement mechanism 131 can move waveguide structure 5 in, for example, a direction of optical axis A1 of light L1. Movement mechanism 131 can further move waveguide structure 5 in a direction orthogonal to optical axis A1 of light L1. The direction orthogonal to optical axis A1 of light L1 may include, for example, at least one of the thickness direction (up and lower direction in FIG. 1) and the width direction (direction orthogonal to a paper surface in FIG. 1) of optical waveguide 3.

Third attachment member 14 is disposed on base body 11. Convergence optical system 6 is installed on a surface (upper surface in FIG. 1) of third attachment member 14 opposite to base body 11.

Support 10 can move waveguide structure 5 relative to light source 2 by movement mechanism 131. Thus, the positional relationship between waveguide structure 5 and light source 2 can be easily set. After positions of waveguide structure 5 and light source 2 are determined by movement mechanism 131, light source 2 or waveguide structure 5 may be fixed such that the positional relationship between light source 2 and waveguide structure 5 does not change. In the case of support 10, waveguide structure 5 is fixed by movement mechanism 131 such that the position of waveguide structure 5 does not change. An adhesive or mechanical means can be used to fix waveguide structure 5.

### [1.1.2 Effects and the Like]

As described above, light-emitting device 1 includes light source 2 that emits light L1 having directionality and having a single wavelength, and waveguide structure 5 that includes optical waveguide 3 that has incident end surface 31 and emission end surface 32, converts the wavelength of light L1 incident from incident end surface 31, and emits light L1 from emission end surface 32, and exterior part 4 that has light transparency and covers optical waveguide 3 such that at least incident end surface 31 and emission end surface 32 are exposed. Exterior part 4 has first surface 41 close to the light source and second surface 42 opposite to first surface 41. Waveguide structure 5 includes light receiving surface 51 including incident end surface 31 and first surface 41, and radiation surface 52 including emission end surface 32 and second surface 42. A position of waveguide structure 5 with respect to light source 2 is determined such that light L1 is incident on light receiving surface 51. Incident range R in which light L1 is incident on light receiving surface 51 includes at least a part of incident end surface 31 and at least a part of first surface 41 such that a part of light L1 is incident on incident end surface 31 and another part of light L1 is incident on first surface 41, passes through the inside of exterior part 4, and is emitted from second surface 42. In this configuration, the plurality of light rays (first emission light L21 and second emission light L22) having different wavelengths can be emitted from light L1 having a single wavelength at desired output ratios and sectional shapes.

In light-emitting device 1, exterior part 4 has outer surface 43 opposite to optical waveguide 3. Light L1 is incident on light receiving surface 51 such that light L1 propagates through the inside of exterior part 4 while being totally reflected by outer surface 43. This configuration can improve the utilization efficiency of light L1.

Light-emitting device 1 further includes convergence optical system 6 that causes light L1 to be incident on light receiving surface 51 between light source 2 and waveguide structure 5. Assuming that the refractive index of exterior part 4 is n and the angle of the outer edge of light L1 with respect to optical axis A1 within a predetermined surface passing through optical axis A1 of light L1 is θ, θ satisfies the following expression.

$$\begin{matrix}[ Math . 5 ] & \\ θ < 90 ° - arcsin \frac{1}{n} & \end{matrix}$$

This configuration can improve the utilization efficiency of light L1.

In light-emitting device 1, convergence optical system 6 has focal point F opposite to light source 2 with respect to light receiving surface 51 of waveguide structure 5. Light source 2 has emission surface 2b from which light L1 is emitted. Assuming that the distance between the surface of convergence optical system 6 facing light receiving surface 51 and light receiving surface 51 is x, the width of light L1 on emission surface 2b within the predetermined surface is a, and the width of optical waveguide 3 within the predetermined surface is b, a is larger than b, and x satisfies the following expression.

$$\begin{matrix}[ Math . 6 ] & \\ 0 \leq x < \frac{a - b}{2 \cdot tan θ} & \end{matrix}$$

This configuration can improve the utilization efficiency of light L1.

Light-emitting device 1 further includes movement mechanism 131 that moves waveguide structure 5 relative to light source 2. With this configuration, it is easy to set the positional relationship between waveguide structure 5 and light source 2.

In light-emitting device 1, one of the light (first emission light L21) emitted from emission end surface 32 and the light (second emission light L22) emitted from second surface 42 is visible light. The other of the light (first emission light L21) emitted from emission end surface 32 and the light (second emission light L22) emitted from second surface 42 is invisible light. Since this configuration can be used by combining visible light and invisible light, usability of light-emitting device 1 can be improved.

In light-emitting device 1, incident end surface 31 and first surface 41 are on an identical plane on light receiving surface 51. This configuration can improve the utilization efficiency of light L1.

### 1.2 Second Exemplary Embodiment

### [1.2.1 Configuration]

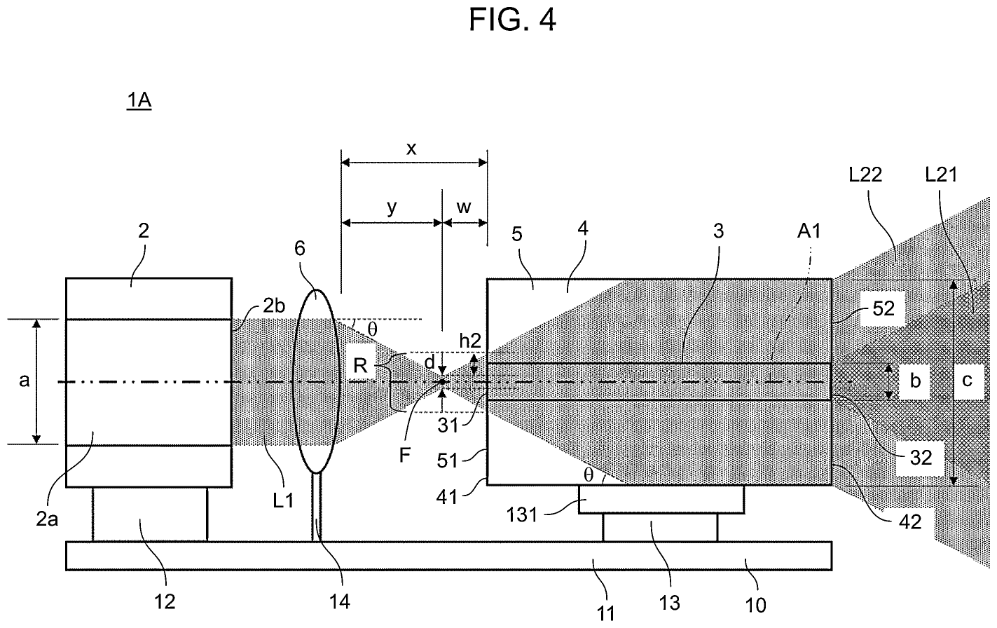

FIG. 4 is a schematic side view of a configuration example of light-emitting device 1A of a second exemplary embodiment. Similarly to light-emitting device 1 of FIG. 1, light-emitting device 1A of FIG. 4 includes light source 2, waveguide structure 5, and convergence optical system 6, but is different from light-emitting device 1 of FIG. 1 in the positional relationship between waveguide structure 5 and convergence optical system 6.

Light-emitting device 1A includes convergence optical system 6 that causes light L1 to be incident on light receiving surface 51 between light source 2 and waveguide structure 5. An angle of an outer edge of light L1 with respect to optical axis A1 within a predetermined surface passing through optical axis A1 of light L1 is θ[°], a refractive index of the exterior part is n, and a refractive index of air is n0. In this case, a critical angle on outer surface 43 of exterior part 4 is given by n×sin (90°−θ)=n0×sin 90°. When refractive index n0 of the air is set to 1, in order for light L1 from light source 2 to be totally reflected by outer surface 43 of exterior part 4, θ may satisfy Expression (1) as in the first exemplary embodiment.

Accordingly, convergence optical system 6 is set such that θ satisfies Expression (1). Thus, since light L1 from light source 2 is totally reflected by outer surface 43 of exterior part 4, utilization efficiency of light L1 can be improved.

In light-emitting device 1A, the positional relationship between light source 2 and waveguide structure 5 is set in consideration of the utilization efficiency of light L1. More specifically, light-emitting device 1 is configured such that all of light L1 from light source 2 is incident on light receiving surface 51 of waveguide structure 5 via convergence optical system 6. That is, incident region R is included in light receiving surface 51 without protruding from light receiving surface 51.

Unlike light-emitting device 1 of FIG. 1, in light-emitting device 1A of FIG. 4, convergence optical system 6 has focal point F on the same side as light source 2 with respect to light receiving surface 51 of waveguide structure 5. In FIG. 4, focal point F is virtually illustrated for easy understanding of description. That is, in light-emitting device 1A of FIG. 4, after light L1 passing through convergence optical system 6 is focused, light L1 is incident on light receiving surface 51 of waveguide structure 5.

In light-emitting device 1A of FIG. 4, light L1 passing through convergence optical system 6 is focused before being incident on waveguide structure 5. A spot diameter (minimum spot diameter) at this time is represented by the sum of aberration and diffraction limit of the lens of convergence optical system 6. In a case where light is ideally condensed in convergence optical system 6, since an aplanatic lens can be used as an aspherical lens or the like, the aberration of the lens can be set to 0. In this case, the minimum spot diameter is equal to the diffraction limit. The diffraction limit is given by 1.27×Cm×(λ×f/D). Cm is a mode coefficient, λ is a wavelength of light, f is a focal length of convergence optical system 6, and D is a diameter of light incident on convergence optical system 6. In a case where light has an ideal Gaussian distribution, Cm=1. In this case, when the minimum spot diameter is d, d=1.27×(2×f/D). In a commercially available lens, a spherical lens has a small value of f/D. For example, the minimum value of f/D of the commercially available lens is about 0.575. In this case, d=0.72. That is, d=0.72 may be satisfied in an ideal condensing state. However, in practice, d is larger than 0.72 due to influence of various aberrations.

In FIG. 4, a spread of light L1 within a predetermined surface passing through optical axis A1 of light L1 is h2. A width of incident region R within the predetermined surface is represented by d+2×h2. Incident region R includes incident end surface 31 of optical waveguide 3 and first surface 41 of exterior part 4, but is set not to protrude from first surface 41 of exterior part 4. In this case, assuming that a width of optical waveguide 3 within the predetermined surface is b and a width of waveguide structure 5 within the predetermined surface is c, the width of incident region R satisfies the following Expression (5).

$$\begin{matrix}[ Math . 7 ] & \\ b < d + 2 \cdot h 2 < c & ( 5 )\end{matrix}$$

A distance from focal point F to light receiving surface 51 is defined as w. In a geometric relationship in FIG. 4, a relationship between spread component h2 and distance w is tan θ=h2/w. When h2 is removed from Expression (5) by using this relational expression, the following Expression (6) is obtained.

$$\begin{matrix}[ Math . 8 ] & \\ \frac{b - d}{2 \cdot tan θ} < w < \frac{c - d}{2 \cdot tan θ} & ( 6 )\end{matrix}$$

In FIG. 4, assuming that a distance between a surface of convergence optical system 6 facing light receiving surface 51 and light receiving surface 51 is x and a distance between the surface of the convergence optical system 6 facing light receiving surface 51 and focal point F is y, x=y+w. When w is removed from Expression (6) by using this relational expression, the following Expression (7) is obtained.

$$\begin{matrix}[ Math . 9 ] & \\ \frac{b - d}{2 \cdot tan θ} + y < x < \frac{c - d}{2 \cdot tan θ} + y & ( 7 )\end{matrix}$$

From Expression (7), it can be seen that x is not restricted by width a of light L1 on emission surface 2b within the predetermined surface in a case where light L1 is incident on light receiving surface 51 of waveguide structure 5 after the light is focused. That is, a positional relationship between convergence optical system 6 and waveguide structure 5 can be set regardless of width a of light L1 on emission surface 2b within the predetermined surface. That is, a degree of freedom in setting incident range R is improved.

In light-emitting device 1A, it is preferable that Expressions (1) and (7) are established with respect to any predetermined surface passing through optical axis A1 of light L1.

### [1.2.2 Effects and the Like]

In light-emitting device 1A described above, convergence optical system 6 has focal point F on the same side as light source 2 with respect to light receiving surface 51 of waveguide structure 5. Assuming that the distance between the surface of convergence optical system 6 facing light receiving surface 51 and light receiving surface 51 is x, that a distance between the surface of convergence optical system 6 facing light receiving surface 51 and focal point F is y, a width of optical waveguide 3 within the predetermined surface is b, a width of waveguide structure 5 within the predetermined surface is c, and a width of light L1 at focal point F within the predetermined surface is d, x satisfies the following expression.

$$\begin{matrix}[ Math . 10 ] & \\ \frac{b - d}{2 \cdot tan θ} + y < x < \frac{c - d}{2 \cdot tan θ} + y & \end{matrix}$$

This configuration can improve the utilization efficiency of light L1.

### 1.3 Third Exemplary Embodiment

### [1.3.1 Configuration]

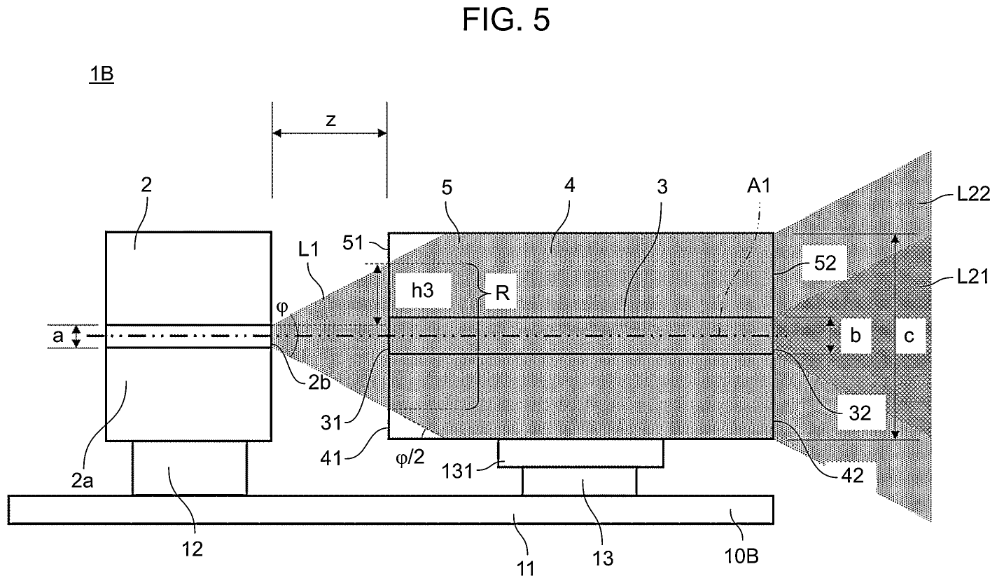

FIG. 5 is a schematic side view of a configuration example of light-emitting device 1B of a third exemplary embodiment. Similarly to light-emitting device 1 of FIG. 1, light-emitting device 1B of FIG. 5 includes light source 2 and waveguide structure 5, but does not include convergence optical system 6 unlike light-emitting device 1 of FIG. 1.

In light-emitting device 1B, in order to efficiently transmit light L1 from light source 2 without being output to an outside of waveguide structure 5, light L1 from light source 2 may be totally reflected at a boundary surface between exterior part 4 and surrounding air, that is, outer surface 43 of exterior part 4. Thus, in light-emitting device 1B, light L1 is incident on light receiving surface 51 such that light L1 propagates through the inside of exterior part 4 while being totally reflected by outer surface 43.

In the present exemplary embodiment, light source 2 and waveguide structure 5 are positioned such that light L1 from light source 2 is directly incident on light receiving surface 51 of waveguide structure 5. There is no optical component acting on light L1 from light source 2 between light source 2 and waveguide structure 5. In light-emitting device 1B, since it is not necessary to use an optical component such as convergence optical system 6, the number of components can be reduced, and the configuration of light-emitting device 1B can be simplified.

In light-emitting device 1B, in order to efficiently transmit light L1 from light source 2 without being output to an outside of waveguide structure 5, light L1 from light source 2 may be totally reflected at a boundary surface between exterior part 4 and surrounding air, that is, outer surface 43 of exterior part 4. Thus, in light-emitting device 1B, light L1 is incident on light receiving surface 51 such that light L1 propagates through the inside of exterior part 4 while being totally reflected by outer surface 43.

In the present exemplary embodiment, in light-emitting device 1B, there is no convergence optical system 6 between light source 2 and waveguide structure 5, and light L1 from light source 2 is directly incident on light receiving surface 51 of waveguide structure 5. Light L1 has directionality, and is, for example, laser beam. The laser beam is generally considered to have good straightness, but actually travels while diverging at a certain angle in many cases. Here, a divergence angle of a light flux of light L1 on emission surface 2b within a predetermined surface passing through optical axis A1 of light L1 is φ[°]. A refractive index of the exterior part is n, and a refractive index of air is n0. In this case, a critical angle on outer surface 43 of exterior part 4 is given by n×sin(90°−φ/2)=n0×sin 90°. When refractive index n0 of the air is set to 1, in order for light L1 from light source 2 to be totally reflected by outer surface 43 of exterior part 4, q may satisfy the following Expression (8).

$$\begin{matrix}[ Math . 11 ] & \\ φ < 180 ° - 2 \cdot arcsin \frac{1}{n} & ( 8 )\end{matrix}$$

Accordingly, light source 2 is set such that φ satisfies Expression (8). Thus, since light L1 from light source 2 is totally reflected by outer surface 43 of exterior part 4, utilization efficiency of light L1 can be improved.

In light-emitting device 1B, the positional relationship between light source 2 and waveguide structure 5 is set in consideration of the utilization efficiency of light L1. More specifically, light-emitting device 1B is configured such that all of light L1 from light source 2 is incident on light receiving surface 51 of waveguide structure 5. That is, incident region R is included in light receiving surface 51 without protruding from light receiving surface 51.

In light-emitting device 1B, assuming that a width of light L1 on emission surface 2b within the predetermined surface is a, a width of optical waveguide 3 within the predetermined surface is b, and a width of waveguide structure 5 within the predetermined surface is c, a, b, and c satisfy a relationship of a<b<c.

In FIG. 5, a spread of light L1 within a predetermined surface passing through optical axis A1 of light L1 is h3. A width of incident region R within the predetermined surface is represented by a+2×h3. Incident region R includes incident end surface 31 of optical waveguide 3 and first surface 41 of exterior part 4, but is set not to protrude from first surface 41 of exterior part 4. The width of incident region R satisfies the following Expression (9).

$$\begin{matrix}[ Math . 12 ] & \\ b < a + 2 \cdot h 3 < c & ( 9 )\end{matrix}$$

When a distance between emission surface 2b and light receiving surface 51 is z, tan(φ/2)=h3/z. When h3 is removed from Expression (9) by using this relational expression, the following Expression (10) is obtained.

$$\begin{matrix}[ Math . 13 ] & \\ \frac{b - a}{2 \cdot tan \frac{φ}{2}} < z < \frac{c - a}{2 \cdot tan \frac{φ}{2}} & ( 10 )\end{matrix}$$

Thus, incident region R includes incident end surface 31 of optical waveguide 3 and first surface 41 of exterior part 4, but can be prevented from protruding from first surface 41 of exterior part 4, and the utilization efficiency of light L1 can be improved.

In light-emitting device 1B, it is preferable that Expressions (8) and (10) are established with respect to any predetermined surface passing through optical axis A1 of light L1.

Light-emitting device 1B of FIG. 5 further includes support 10B that supports light source 2 and waveguide structure 5. In the present exemplary embodiment, light source 2 and waveguide structure 5 are attached to support 10B, and thus, mutual positional relationships are defined. Support 10B of FIG. 5 includes base body 11, first attachment member 12, and second attachment member 13, but is different from support 10 of FIG. 1 in that third attachment member 14 is not provided. Similarly to support 10, support 10B can move waveguide structure 5 relative to light source 2 by movement mechanism 131. Thus, the positional relationship between waveguide structure 5 and light source 2 can be easily set.

### [1.3.2 Effects and the Like]

In light-emitting device 1B described above, light source 2 has emission surface 2b from which light L1 is emitted. Light source 2 and waveguide structure 5 are positioned such that light L1 from light source 2 is directly incident on light receiving surface 51 of waveguide structure 5. When a refractive index of exterior part 4 is n, and a divergence angle of a light flux of light L1 on emission surface 2b within the predetermined surface passing through optical axis A1 of light L1 is φ, φ satisfies the following expression.

$$\begin{matrix}[ Math . 14 ] & \\ φ < 180 ° - 2 \cdot arcsin \frac{1}{n} & \end{matrix}$$

This configuration can improve the utilization efficiency of light L1.

In light-emitting device 1B, assuming that a width of light L1 on emission surface 2b within the predetermined surface is a, a width of optical waveguide 3 within the predetermined surface is b, and a width of waveguide structure 5 within the predetermined surface is c, a, b, and c satisfy a relationship of a<b<c. Assuming that a distance between emission surface 2b and light receiving surface 51 is z, z satisfies the following expression.

$$\frac{b - a}{2 \cdot tan \frac{φ}{2}} < z < \frac{c - a}{2 \cdot tan \frac{φ}{2}} \qquad [ Math . 15 ]$$

This aspect can improve the utilization efficiency of light L1.

### 1.4 Fourth Exemplary Embodiment

### [1.4.1 Configuration]

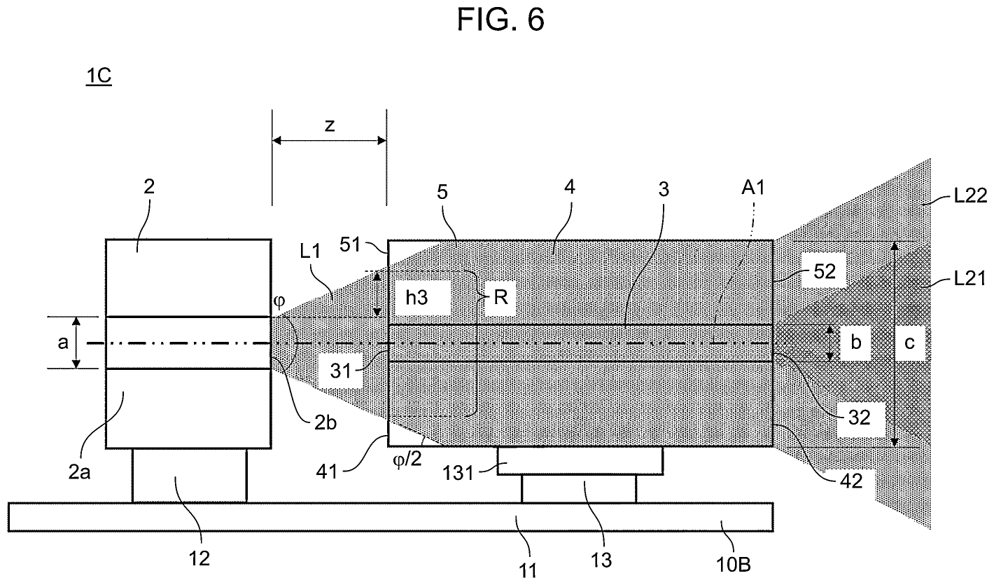

FIG. 6 is a schematic side view of a configuration example of light-emitting device 1C of a fourth exemplary embodiment. Light-emitting device 1C of FIG. 6 is similar to light-emitting device 1B of FIG. 5 in that the light-emitting device includes light source 2 and waveguide structure 5 and does not include convergence optical system 6. However, light-emitting device 1C of FIG. 6 is different from light-emitting device 1B of FIG. 5 in a relationship among width a of light L1 on emission surface 2b within a predetermined surface, width b of optical waveguide 3 within the predetermined surface, and width c of waveguide structure 5 within the predetermined surface.

In light-emitting device 1C, there is no convergence optical system 6 between light source 2 and waveguide structure 5, and light L1 from light source 2 is directly incident on light receiving surface 51 of waveguide structure 5. Light L1 has directionality, and is, for example, laser beam. The laser beam is generally considered to have good straightness, but actually travels while diverging at a certain angle in many cases. Here, a divergence angle of a light flux of light L1 on emission surface 2b within a predetermined surface passing through optical axis A1 of light L1 is φ[°]. A refractive index of the exterior part is n, and a refractive index of air is n0. In this case, a critical angle on outer surface 43 of exterior part 4 is given by n×sin (90°−φ/2)=n0×sin 90°. When refractive index n0 of the air is set to 1, in order for light L1 from light source 2 to be totally reflected by outer surface 43 of exterior part 4, φ may satisfy Expression (8) as in the third exemplary embodiment.

Accordingly, light source 2 is set such that φ satisfies Expression (8). Thus, since light L1 from light source 2 is totally reflected by outer surface 43 of exterior part 4, utilization efficiency of light L1 can be improved.

In light-emitting device 1C, a positional relationship between light source 2 and waveguide structure 5 is set in consideration of the utilization efficiency of light L1. More specifically, light-emitting device 1C is configured such that all of light L1 from light source 2 is incident on light receiving surface 51 of waveguide structure 5. That is, incident region R is included in light receiving surface 51 without protruding from light receiving surface 51.

In light-emitting device 1C, assuming that a width of light L1 on emission surface 2b within the predetermined surface is a, a width of optical waveguide 3 within the predetermined surface is b, and a width of waveguide structure 5 within the predetermined surface is c, a, b, and c satisfy a relationship of b<a<c.

In FIG. 6, a spread of light L1 with a predetermined surface passing through optical axis A1 of light L1 is h3. A width of incident region R within the predetermined surface is represented by a+2×h3. Incident region R includes incident end surface 31 of optical waveguide 3 and first surface 41 of exterior part 4, but is set not to protrude from first surface 41 of exterior part 4. The width of incident region R satisfies Expression (9).

When a distance between emission surface 2b and light receiving surface 51 is z, tan(φ/2)=h3/z. When h3 is removed from Expression (9) by using this relational expression, Expression (10) is obtained.

Here, in light-emitting device 1C, a>b, but z≥0. Accordingly, light-emitting device 1C may satisfy the following Expression (11).

$$\begin{matrix}[ Math . 16 ] & \\ 0 \leq z < \frac{c - a}{2 \cdot tan \frac{φ}{2}} & ( 11 )\end{matrix}$$

Thus, incident region R includes incident end surface 31 of optical waveguide 3 and first surface 41 of exterior part 4, but can be prevented from protruding from first surface 41 of exterior part 4, and the utilization efficiency of light L1 can be improved.

In light-emitting device 1C, it is preferable that Expressions (8) and (11) are satisfied with respect to any predetermined surface passing through optical axis A1 of light L1.

### [1.4.2 Effects and the Like]

In light-emitting device 1C described above, assuming that a width of light L1 on emission surface 2b within the predetermined surface is a, a width of optical waveguide 3 within the predetermined surface is b, and a width of waveguide structure 5 within the predetermined surface is c, a, b, and c satisfy a relationship of b<a<c. Assuming that a distance between emission surface 2b and light receiving surface 51 is z, z satisfies the following expression.

$$0 \leq z < \frac{c - a}{2 \cdot tan \frac{φ}{2}} \qquad [ Math . 17 ]$$

This configuration can improve the utilization efficiency of light L1.

### 1.5 Fifth Exemplary Embodiment

### [1.5.1 Configuration]

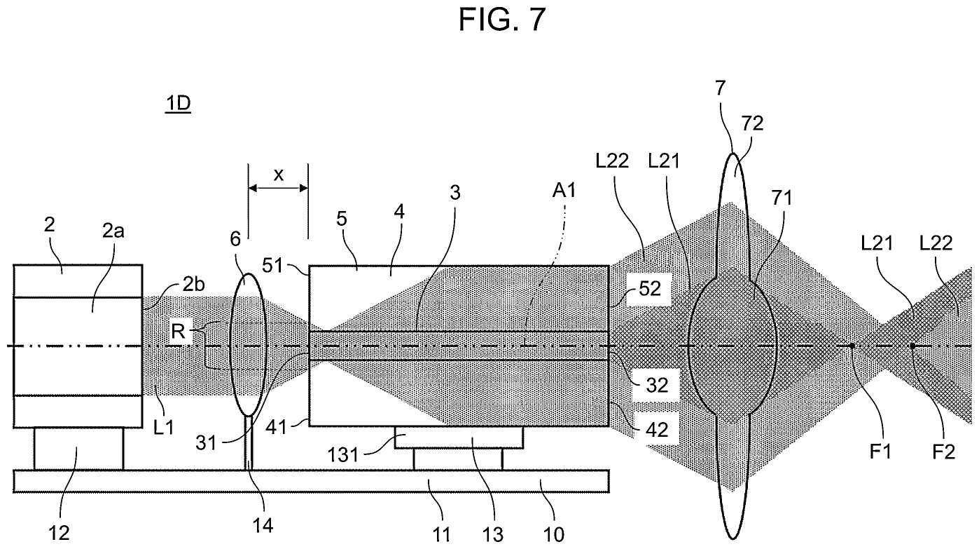

FIG. 7 is a schematic side view of a configuration example of light-emitting device 1D of a fifth exemplary embodiment. Light-emitting device 1D of FIG. 7 includes light source 2, waveguide structure 5, and convergence optical system 6, and further includes shaping optical system 7 on which the light (first emission light L21 and second emission light L22) from radiation surface 52 is incident.

Shaping optical system 7 of FIG. 7 is positioned to face radiation surface 52 of waveguide structure 5. Shaping optical system 7 is used to change at least one of a shape of first emission light L21 emitted from emission end surface 32, a shape of second emission light L22 emitted from second surface 42, and a positional relationship between first emission light L21 and second emission light L22. Shaping optical system 7 may be fixed to, for example, support 10.

In the present exemplary embodiment, as illustrated in FIG. 7, shaping optical system 7 switches positions of first emission light L21 and second emission light L22. That is, on radiation surface 52 of waveguide structure 5, first emission light L21 is positioned inside second emission light L22. However, shaping optical system 7 switches the positions of first emission light L1 and second emission light L1, and thus, second emission light L22 is positioned inside first emission light L21.

In the present exemplary embodiment, shaping optical system 7 of FIG. 7 is an aspherical lens. In particular, shaping optical system 7 is an aspherical lens in which a focal length is shortened by reducing curvature of a central portion and the focal length is lengthened by increasing curvature of an outer peripheral portion. More specifically, shaping optical system 7 includes first lens unit 71 and second lens unit 72. First lens unit 71 is in the central portion of shaping optical system 7, and receives first emission light L21 from emission end surface 32 of optical waveguide 3 of waveguide structure 5. First lens unit 71 acts as a convex lens that condenses first emission light L21. Second lens unit 72 is in the outer peripheral portion of shaping optical system 7, and receives second emission light L22 from second surface 42 of exterior part 4 of waveguide structure 5. Second lens unit 72 acts as a convex lens that condenses second emission light L22. In shaping optical system 7, first emission light L21 spreads farther than focal point F1, and second emission light L22 spreads farther than focal point F2. A focal length of first lens unit 71 is shorter than a focal length of second lens unit 72. Accordingly, as illustrated in FIG. 7, focal point F1 of first lens unit 71 is positioned closer to shaping optical system 7 than focal point F2 of second lens unit 72. Accordingly, second emission light L22 is positioned inside first emission light L21 at a position farther than focal point F2. That is, second emission light L22 is surrounded by first emission light L21 within a surface orthogonal to optical axis A1 of light L1.

For example, in a case where second emission light L22 is more suitable for machining an object than first emission light L21, shaping optical system 7 switches the positions of first emission light L21 and second emission light L22. Thus, since first emission light L21 can be disposed on a center side, case of machining by light-emitting device 1 is improved.

### [1.5.2 Effects and the Like]

In light-emitting device 1D described above, light-emitting device 1D further includes shaping optical system 7 on which the light (first emission light L21 and second emission light L22) from radiation surface 52 is incident. Shaping optical system 7 changes a positional relationship between first emission light L21 and second emission light L22. With this configuration, it is easy to set shapes and positional relationships of the plurality of light rays (first emission light L21 and second emission light L22) having different wavelengths.

In light-emitting device 1D, shaping optical system 7 includes an aspherical lens. With this configuration, it is easy to set shapes and positional relationships of the plurality of light rays (first emission light L21 and second emission light L22) having different wavelengths.

In light-emitting device 1D, shaping optical system 7 switches the positions of first emission light L1 and second emission light L1. With this configuration, it is easy to set shapes and positional relationships of the plurality of light rays (first emission light L21 and second emission light L22) having different wavelengths.

### 1.6 Sixth Exemplary Embodiment

### [1.6.1 Configuration]

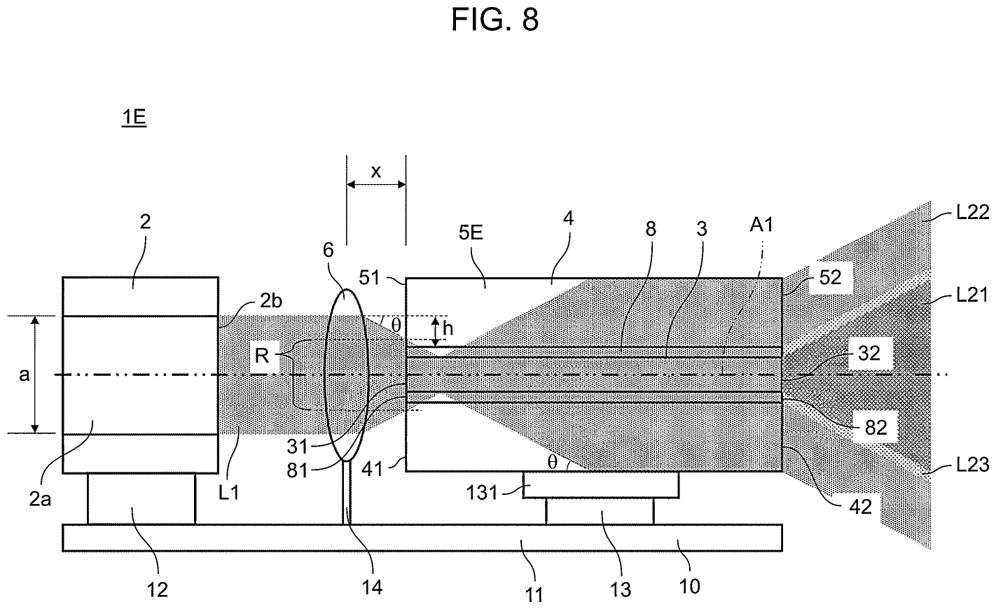

FIG. 8 is a schematic side view of a configuration example of light-emitting device 1E of a sixth exemplary embodiment. Light-emitting device 1E of FIG. 8 includes light source 2, waveguide structure 5E, convergence optical system 6, and support 10.

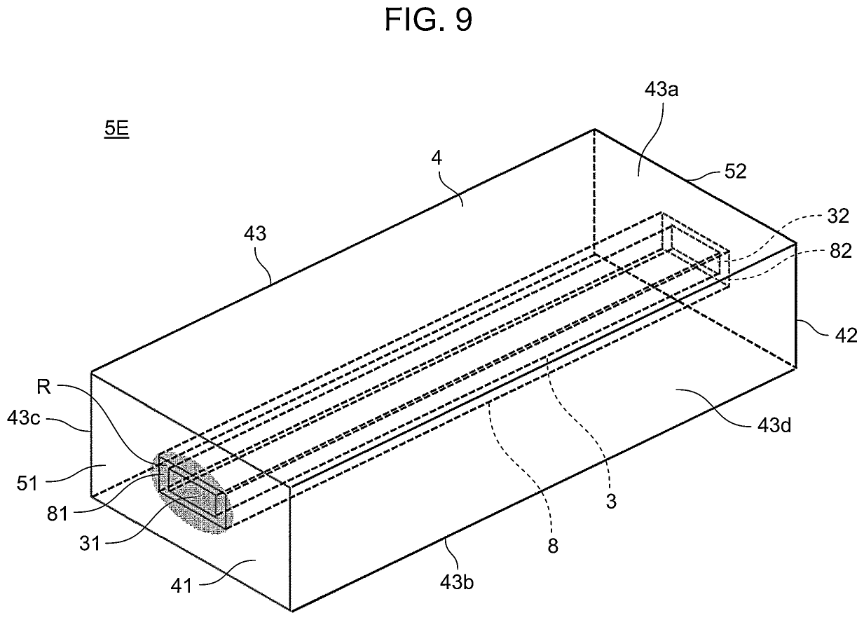

FIG. 9 is a perspective view of a configuration example of waveguide structure 5E of light-emitting device 1E of FIG. 8. Waveguide structure 5E includes optical waveguide 3, exterior part 4, and intermediate part 8.

Intermediate part 8 is between optical waveguide 3 and exterior part 4. Intermediate part 8 of FIG. 9 covers optical waveguide 3. Intermediate part 8 covers optical waveguide 3 such that incident end surface 31 and emission end surface 32 of optical waveguide 3 are exposed. In the present exemplary embodiment, intermediate part 8 has a rectangular parallelepiped shape. Intermediate part 8 covers optical waveguide 3 such that a length direction of intermediate part 8 coincides with a length direction of optical waveguide 3. A center of optical waveguide 3 within a surface orthogonal to the length direction coincides with a center of intermediate part 8 within a surface orthogonal to the length direction. Intermediate part 8 has first intermediate surface 81 and second intermediate surface 82 as both surfaces of intermediate part 8 in the length direction. First intermediate surface 81 is a surface of intermediate part 8 close to light source 2. Second intermediate surface 82 is a surface of intermediate part 8 opposite to first intermediate surface 81. First intermediate surface 81 and second intermediate surface 82 are rectangular. Incident end surface 31 and emission end surface 32 of optical waveguide 3 are exposed to first intermediate surface 81 and second intermediate surface 82 of intermediate part 8, respectively.

Intermediate part 8 has light transparency. Intermediate part 8 emits light L1 incident on light receiving surface 51 side, that is, intermediate part 8 from first intermediate surface 81 to radiation surface 52 side, that is, second intermediate surface 82 to an outside of intermediate part 8. In the present exemplary embodiment, intermediate part 8 converts a wavelength of light L1 incident from first intermediate surface 81 and emits light L1 from second intermediate surface 82. Intermediate part 8 converts the wavelength of light L1 into a wavelength different from a wavelength of first emission light L21 from optical waveguide 3. In the present exemplary embodiment, intermediate part 8 is a wavelength conversion element using a non-linear optical effect. Intermediate part 8 is made of, for example, a non-linear optical crystal. A phase matching method of the non-linear optical crystal is not particularly limited, and examples thereof include quasi-phase matching and birefringence phase matching (critical phase matching, non-critical phase matching, or the like).

Exterior part 4 covers optical waveguide 3 and intermediate part 8. Exterior part 4 of FIG. 9 covers optical waveguide 3 and intermediate part 8 such that incident end surface 31 and emission end surface 32 of optical waveguide 3 and first intermediate surface 81 and second intermediate surface 82 of intermediate part 8 are exposed. In the present exemplary embodiment, exterior part 4 has a rectangular parallelepiped shape. Exterior part 4 covers optical waveguide 3 such that a length direction of exterior part 4 coincides with the length direction of optical waveguide 3. A center of optical waveguide 3 within a surface orthogonal to the length direction coincides with a center of exterior part 4 within a surface orthogonal to the length direction. First intermediate surface 81 and second intermediate surface 82 of intermediate part 8 are exposed to first surface 41 and second surface 42 of exterior part 4 in the length direction, respectively.

In waveguide structure 5E of FIG. 9, light receiving surface 51 includes incident end surface 31 of optical waveguide 3, first surface 41 of exterior part 4, and first intermediate surface 81 of intermediate part 8. Incident end surface 31 is a central region of light receiving surface 51. First surface 41 is a region around light receiving surface 51 and surrounds incident end surface 31. First intermediate surface 81 is a region of light receiving surface 51 between first surface 41 and incident end surface 31, and surrounds incident end surface 31. In the present exemplary embodiment, as illustrated in FIG. 8, on light receiving surface 51, incident end surface 31, first surface 41, and first intermediate surface 81 are positioned on an identical plane. That is, incident end surface 31, first surface 41, and first intermediate surface 81 are flush with each other. Thus, utilization efficiency of light L1 can be improved.

In waveguide structure 5E of FIG. 9, radiation surface 52 includes emission end surface 32 of optical waveguide 3, second surface 42 of exterior part 4, and second intermediate surface 82 of intermediate part 8. Emission end surface 32 is a central region of radiation surface 52. Second surface 42 is a region around radiation surface 52 and surrounds emission end surface 32. Second intermediate surface 82 is a region of radiation surface 52 between second surface 42 and emission end surface 32, and surrounds emission end surface 32. In the present exemplary embodiment, as illustrated in FIG. 8, on radiation surface 52, emission end surface 32, second surface 42, and second intermediate surface 82 are positioned on an identical plane. That is, emission end surface 32, second surface 42, and second intermediate surface 82 are flush with each other. Thus, utilization efficiency of light L1 can be improved.

Light L1 incident on optical waveguide 3 from incident end surface 31 of optical waveguide 3 of waveguide structure 5E propagates in the length direction of optical waveguide 3 while being reflected at a boundary surface between optical waveguide 3 and intermediate part 8, and a wavelength thereof is converted in a procedure of propagation. Light L1 of which the wavelength is converted by optical waveguide 3 is emitted, as first emission light L21, from emission end surface 32 to an outside of waveguide structure 5E.

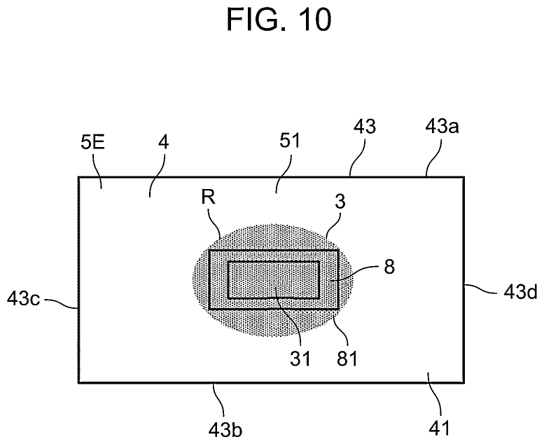

FIG. 10 is a schematic diagram of light receiving surface 51 of waveguide structure 5E of FIG. 9. As illustrated in FIG. 10, incident range R in which light L1 is incident on light receiving surface 51 includes at least a part of incident end surface 31 and at least a part of first surface 41. On light receiving surface 51, since first intermediate surface 81 is between incident end surface 31 and first surface 41, incident range R also includes at least a part of first intermediate surface 81. In the present exemplary embodiment, light-emitting device 1E is configured such that light L1 from light source 2 is incident on not only optical waveguide 3 but also exterior part 4 and intermediate part 8.

Since incident range R includes not only incident end surface 31 but also first surface 41, exterior part 4 can emit light L1 incident on first surface 41 from second surface 42. That is, light L1 incident on exterior part 4 from first surface 41 of exterior part 4 of waveguide structure 5E propagates in the length direction of exterior part 4 while being reflected by outer surface 43 of exterior part 4 opposite to optical waveguide 3. Light L1 propagating through exterior part 4 is emitted, as second emission light L22, from second surface 42 to the outside of waveguide structure 5E.

Since incident range R includes not only incident end surface 31 but also first intermediate surface 81, intermediate part 8 can emit light L1 incident on first intermediate surface 81 from second intermediate surface 82. That is, light L1 incident on intermediate part 8 from first intermediate surface 81 of intermediate part 8 of waveguide structure 5E propagates in the length direction of intermediate part 8 while being reflected at a boundary surface between intermediate part 8 and optical waveguide 3 or exterior part 4. Light L1 propagating through intermediate part 8 is emitted, as third emission light L23, from second intermediate surface 82 to the outside of waveguide structure 5E.

As described above, light-emitting device 1E outputs first emission light L21 from optical waveguide 3, second emission light L22 from exterior part 4, and third emission light L23 from intermediate part 8 in response to the input of light L1 from light source 2. In light-emitting device 1E, first emission light L21, second emission light L22, and third emission light L23 have different wavelengths. In light-emitting device 1E, an output ratio of the plurality of light rays (first emission light L21, second emission light L22, and third emission light L23) having different wavelengths can be mainly set to a desired output ratio depending on a size and a position of incident range R on light receiving surface 51. In light-emitting device 1E, sectional shapes of the plurality of light rays (first emission light L21, second emission light L22, and third emission light L23) can be mainly set to desired shapes depending on the shapes of optical waveguide 3, exterior part 4, and intermediate part 8 in waveguide structure 5E on a surface orthogonal to optical axis A1 of light L1. That is, light-emitting device 1E can emit the plurality of light rays (first emission light L21, second emission light L22, and third emission light L23) having different wavelengths from light L1 having a single wavelength at desired output ratios and sectional shapes.

### [1.6.2. Effects and the Like]

In light-emitting device 1E described above, waveguide structure 5E further includes intermediate part 8 between optical waveguide 3 and exterior part 4. Intermediate part 8 has light transparency, and emits light L1 incident on one or more intermediate parts 8 from light receiving surface 51 side to the outside of intermediate part 8 from radiation surface 52 side. In this configuration, the plurality of light rays (first emission light L21, second emission light L22, and third emission light L23) having different wavelengths can be emitted from light L1 having a single wavelength at desired output ratios and sectional shapes.

### 2. Modifications

The exemplary embodiments of the present disclosure are not limited to the above exemplary embodiments. The above exemplary embodiments can be variously modified in accordance with design and the like as long as an object of the present disclosure can be achieved. Hereinafter, modifications of the above exemplary embodiments will be listed. The modifications to be described below can be applied in appropriate combination.

### 2.1 Modification 1

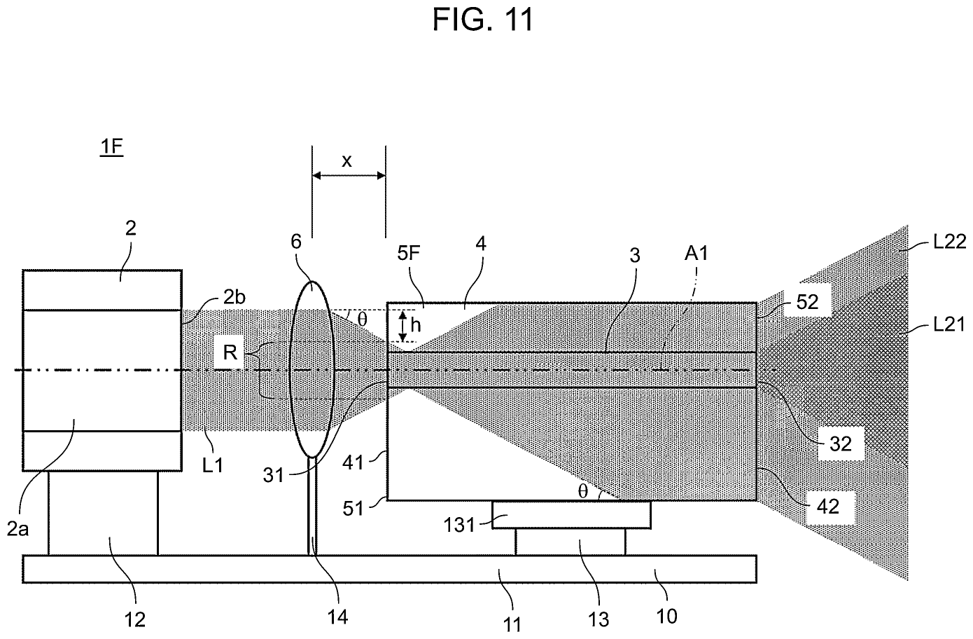

FIG. 11 is a schematic side view of a configuration example of light-emitting device 1F of Modification 1. Light-emitting device 1F of FIG. 11 includes light source 2, waveguide structure 5F, and convergence optical system 6.

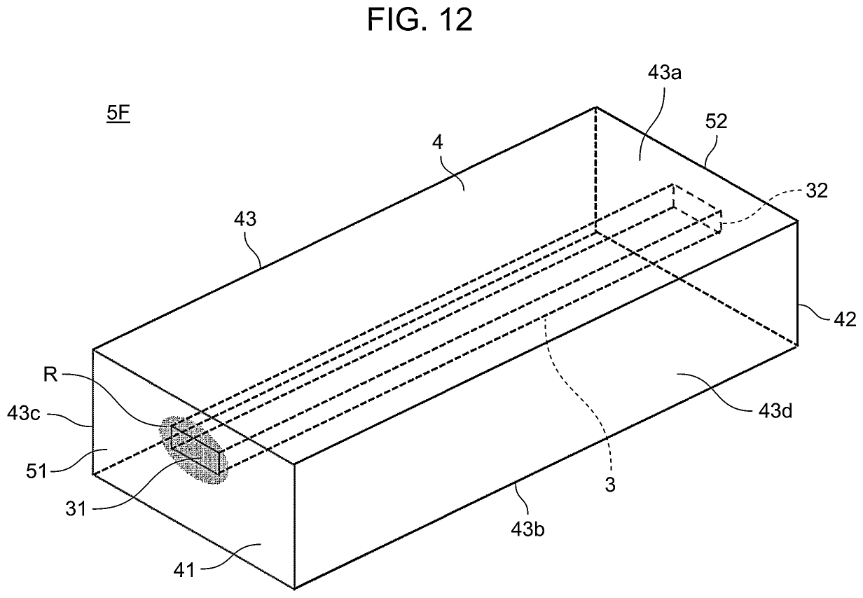

FIG. 12 is a perspective view of a configuration example of waveguide structure 5F of light-emitting device 1F of FIG. 11. Similarly to waveguide structure 5 of FIG. 2, waveguide structure 5F includes optical waveguide 3 and exterior part 4, but a positional relationship between optical waveguide 3 and exterior part 4 is different from waveguide structure 5 of FIG. 2.

In FIG. 12, a center of optical waveguide 3 within a surface orthogonal to a length direction does not coincide with a center of exterior part 4 within a surface orthogonal to a length direction. The center of optical waveguide 3 within the surface orthogonal to the length direction is shifted in a width direction of exterior part 4 from the center of exterior part 4 within the surface orthogonal to the length direction. More specifically, the center of optical waveguide 3 within the surface orthogonal to the length direction is between the center of exterior part 4 within the surface orthogonal to the length direction and third surface 43a of exterior part 4.

In waveguide structure 5F, a region between optical waveguide 3 and third surface 43a of exterior part 4 on radiation surface 52 is narrower than a region between optical waveguide 3 and fourth surface 43b of exterior part 4. Thus, second emission light L22 on third surface 43a side of exterior part 4 with respect to optical waveguide 3 can be set to be thinner than second emission light L22 on fourth surface 43b of exterior part 4 close to optical waveguide 3. As described above, sectional shapes of a plurality of light rays (first emission light L21 and second emission light L22) having different wavelengths emitted from waveguide structure 5F can be determined by a positional relationship between optical waveguide 3 and exterior part 4.

As described above, the center of optical waveguide 3 within the surface orthogonal to the length direction and the center of exterior part 4 within the surface orthogonal to the length direction do not necessarily coincide with each other. The positional relationship between optical waveguide 3 and exterior part 4 within a surface orthogonal to optical axis A1 of light L1 can be set such that the sectional shapes of the plurality of light rays (first emission light L21 and second emission light L22) having different wavelengths emitted from waveguide structure 5F become desired sectional shapes.

### 2.2 Modification 2

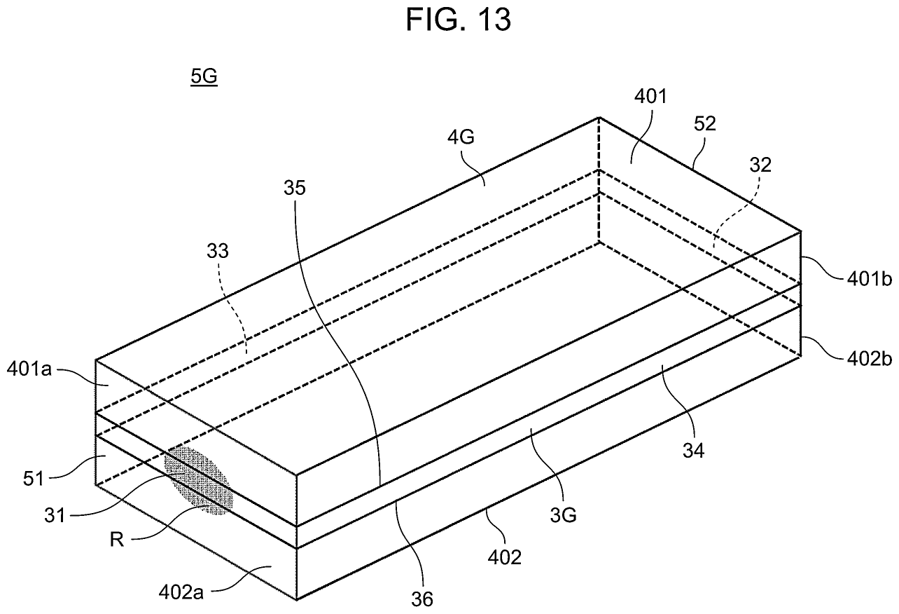

FIG. 13 is a perspective view of a configuration example of waveguide structure 5G of light-emitting device of Modification 2. Waveguide structure 5G can be used instead of waveguide structure 5 in, for example, the first to fifth exemplary embodiments.

Waveguide structure 5G of FIG. 13 includes optical waveguide 3G and exterior part 4G.

Optical waveguide 3G has a hexahedron shape, but has a larger dimension in a width direction than optical waveguide 3 of FIG. 1.

Exterior part 4G covers optical waveguide 3G. Exterior part 4G of FIG. 13 covers optical waveguide 3G such that incident end surface 31 and emission end surface 32 of optical waveguide 3G and both side surfaces 33 and 34 of optical waveguide 3G in the width direction are exposed.

In FIG. 13, exterior part 4G includes first exterior part 401 and second exterior part 402. Optical waveguide 3G is positioned between first exterior part 401 and second exterior part 402 in a thickness direction of optical waveguide 3G. First exterior part 401 covers first surface 35 of optical waveguide 3G in the thickness direction, and second exterior part 402 covers second surface 36 of optical waveguide 3G in the thickness direction. First exterior part 401 and second exterior part 402 have rectangular parallelepiped shapes. First exterior part 401 has first surface 401a and second surface 401b of first exterior part 401 in a length direction. First surface 401a is a surface of first exterior part 401 close to light source 2. Second surface 401b is a surface of first exterior part 401 opposite to first surface 401a. Second exterior part 402 has first surface 402a and second surface 402b of second exterior part 402 in a length direction. First surface 402a is a surface of second exterior part 402 close to light source 2. Second surface 402b is a surface of second exterior part 402 opposite to first surface 402a.

In waveguide structure 5G of FIG. 13, light receiving surface 51 includes incident end surface 31 of optical waveguide 3G and first surfaces 401a and 402a of exterior part 4G. Incident end surface 31 is a central region of light receiving surface 51 of waveguide structure 5G in a thickness direction. First surfaces 401a and 402a are regions on both sides of incident end surface 31 in the thickness direction of waveguide structure 5G. In FIG. 13, on light receiving surface 51, incident end surface 31 and first surfaces 401a and 402a are also positioned on an identical plane.

In waveguide structure 5G of FIG. 13, radiation surface 52 includes emission end surface 32 of optical waveguide 3G and second surfaces 401b and 402b of exterior part 4G. Emission end surface 32 is a central region of radiation surface 52 of waveguide structure 5G in the thickness direction. Second surfaces 401b and 402b are regions on both sides of emission end surface 32 in the thickness direction of waveguide structure 5G. In FIG. 13, on radiation surface 52, emission end surface 32 and second surfaces 401b and 402b are positioned on an identical plane.

Since incident range R includes not only incident end surface 31 but also first surfaces 401a and 402a, exterior part 4G can emit light L1 incident on first surfaces 401a and 402a from second surfaces 401b and 402b. In waveguide structure 5G of FIG. 13, since exterior part 4G is present in the thickness direction of optical waveguide 3G, first emission light L21 and second emission light L22 are present. On the other hand, exterior part 4G is not present in the width direction of optical waveguide 3G. Thus, in the width direction of optical waveguide 3G, only one of first emission light L21 and second emission light L22 is present. Thus, there is no light having a different wavelength in the width direction of optical waveguide 3G.

### 2.3 Modification 3

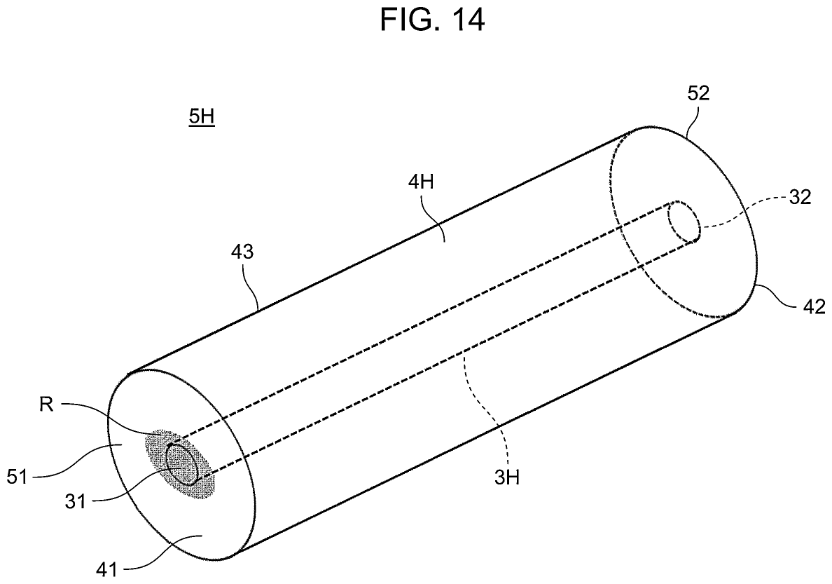

FIG. 14 is a perspective view of a configuration example of waveguide structure 5H of a light-emitting device of Modification 3. Waveguide structure 5H can be used instead of waveguide structure 5 in, for example, the first to fifth exemplary embodiments.

Waveguide structure 5H of FIG. 14 includes optical waveguide 3H and exterior part 4H. Optical waveguide 3H of FIG. 14 has a columnar shape. In FIG. 14, incident end surface 31 and emission end surface 32 are both surfaces in a length direction (axial direction) of optical waveguide 3. Incident end surface 31 and emission end surface 32 are circular. Exterior part 4H of FIG. 14 covers optical waveguide 3H. Exterior part 4H of FIG. 14 covers optical waveguide 3 such that incident end surface 31 and emission end surface 32 of optical waveguide 3H are exposed. In FIG. 14, exterior part 4H has a columnar shape. Exterior part 4H covers optical waveguide 3H such that a length direction of exterior part 4H coincides with the length direction of optical waveguide 3H. A center of optical waveguide 3H within a surface orthogonal to the length direction coincides with a center of exterior part 4H within the surface orthogonal to the length direction.

In waveguide structure 5H of FIG. 14, a sectional shape of first emission light L21 is a circular shape, and a sectional shape of second emission light L22 is an annular shape surrounding first emission light L21. That is, a sectional shape of light emitted from waveguide structure 5H is concentric such that second emission light L22 surrounds an outer periphery of first emission light L21.

### 2.4 Modification 4

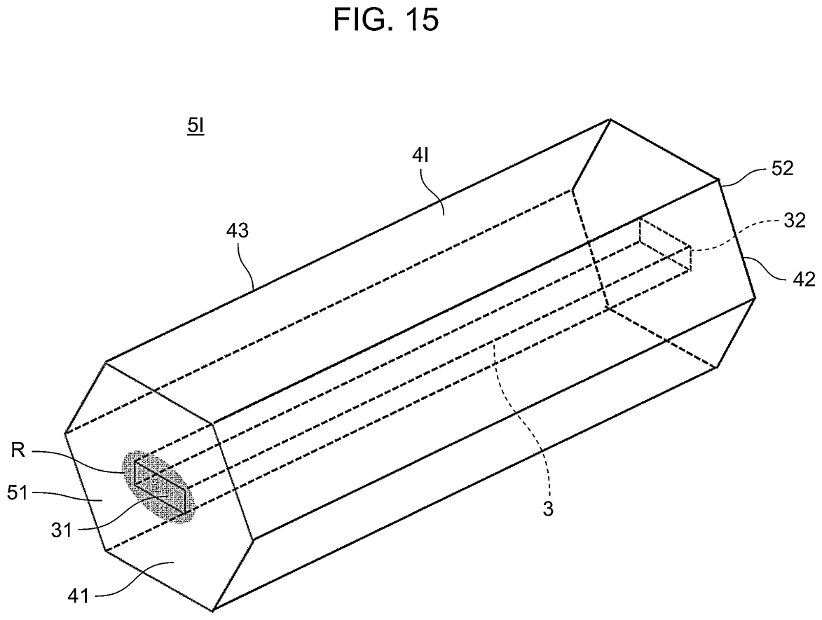

FIG. 15 is a perspective view of a configuration example of a waveguide structure 5I of a light-emitting device of Modification 4. Waveguide structure 5I can be used instead of waveguide structure 5 in, for example, the first to fifth exemplary embodiments.

Waveguide structure 5I of FIG. 15 includes optical waveguide 3 and exterior part 4I. exterior part 4I in FIG. 15 covers optical waveguide 3. Exterior part 4I of FIG. 15 covers optical waveguide 3 such that incident end surface 31 and emission end surface 32 of optical waveguide 3 are exposed. In FIG. 15, exterior part 4I has a hexagonal column shape. Exterior part 4I covers optical waveguide 3 such that a length direction of exterior part 4I coincides with length direction A of optical waveguide 3. The center of optical waveguide 3 in the surface orthogonal to the length direction coincides with the center of exterior part 4I in the surface orthogonal to the length direction.

In waveguide structure 5I of FIG. 15, the sectional shape of first emission light L21 is a rectangular shape, and the sectional shape of second emission light L22 is a hexagonal frame shape surrounding first emission light L21.

### 2.5 Modification 5

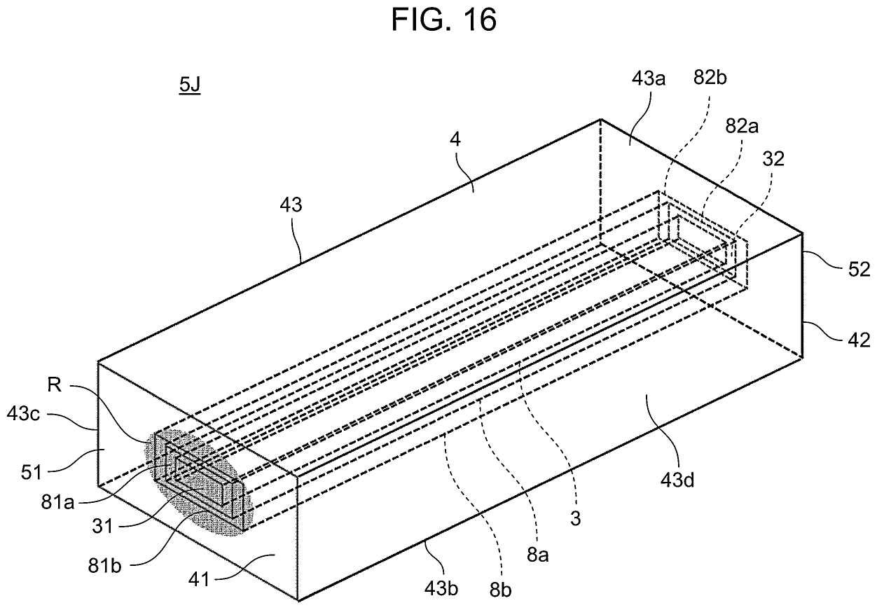

FIG. 16 is a perspective view of a configuration example of waveguide structure 5J of a light-emitting device of Modification 5. Waveguide structure 5J can be used instead of waveguide structure 5 in, for example, the first to fifth exemplary embodiments.

Waveguide structure 5J of FIG. 16 includes optical waveguide 3, exterior part 4, and a plurality of intermediate parts 8a and 8b. Waveguide structure 5J of FIG. 16 is different from waveguide structure 5E of FIG. 9 in including the plurality of intermediate parts 8a and 8b.

Similarly to intermediate part 8 of FIG. 9, intermediate parts 8a and 8b are between optical waveguide 3 and exterior part 4. Intermediate parts 8a and 8b of FIG. 9 cover optical waveguide 3. Intermediate part 8b is inside intermediate part 8a. That is, intermediate part 8b is between optical waveguide 3 and intermediate part 8a.

Intermediate parts 8a and 8b have light transparency. Intermediate parts 8a and 8b emit light L1 incident on light receiving surface 51 side, that is, intermediate parts 8a and 8b from first intermediate surfaces 81a and 81b to radiation surface 52 side, that is, an outside of intermediate parts 8a and 8b from second intermediate surfaces 82a and 82b. Intermediate parts 8a and 8b convert a wavelength of light L1 incident from first intermediate surfaces 81a and 81b and emit light L1 from second intermediate surfaces 82a and 82b. Intermediate parts 8a and 8b convert the wavelength of light L1 into a wavelength different from a wavelength of first emission light L21 from optical waveguide 3. Intermediate parts 8a and 8b convert the wavelength of light L1 into wavelengths different from each other. Intermediate parts 8a and 8b are, for example, wavelength conversion elements using a non-linear optical effect.

In waveguide structure 5J of FIG. 16, light receiving surface 51 includes incident end surface 31 of optical waveguide 3, first surface 41 of exterior part 4, and first intermediate surfaces 81a and 81b of intermediate parts 8a and 8b. Incident end surface 31 is a central region of light receiving surface 51. First surface 41 is a region around light receiving surface 51 and surrounds incident end surface 31. First intermediate surfaces 81a and 81b are regions of light receiving surface 51 between first surface 41 and incident end surface 31, and surround incident end surface 31. On light receiving surface 51, incident end surface 31, first surface 41, and first intermediate surfaces 81a and 81b are positioned on an identical plane.

In waveguide structure 5J of FIG. 16, radiation surface 52 includes emission end surface 32 of optical waveguide 3, second surface 42 of exterior part 4, and second intermediate surfaces 82a and 82b of intermediate parts 8a and 8b. Emission end surface 32 is a central region of radiation surface 52. Second surface 42 is a region around radiation surface 52 and surrounds emission end surface 32. Second intermediate surfaces 82a and 82b are regions of radiation surface 52 between second surface 42 and emission end surface 32, and surround emission end surface 32. On radiation surface 52, emission end surface 32, second surface 42, and second intermediate surfaces 82a and 82b are positioned on an identical plane.

Since incident range R includes not only incident end surface 31 but also first intermediate surfaces 81a and 81b, intermediate parts 8a and 8b can emit light L1 incident on first intermediate surfaces 81a and 81b from second intermediate surfaces 82a and 82b. Waveguide structure 5J further includes a plurality of intermediate parts 8a and 8b between optical waveguide 3 and exterior part 4. Intermediate parts 8a and 8b have light transparency, and emit light L1 incident on intermediate parts 8a and 8b from light receiving surface 51 side to an outside of intermediate parts 8a and 8b from radiation surface 52 side. In this configuration, the plurality of light rays having different wavelengths can be emitted from light L1 having a single wavelength at desired output ratios and sectional shapes.

### 2.3 Other Modifications

In one modification, light source 2 is not limited to the semiconductor laser, and may be another light source. In addition, an electromagnetic wave source that emits an electromagnetic wave having directionality may be used instead of light source 2.

From the first to sixth exemplary embodiments and Modifications 1 to 5, in the light-emitting device, the sectional shape of the plurality of light rays having different wavelengths emitted from the waveguide structure can be set to desired shapes according to the shapes of the optical waveguide, the exterior part, and the intermediate part in the waveguide structure on the surface orthogonal to the optical axis of the light from the light source.

In one modification, the shape of optical waveguide 3 is not limited to the hexahedral shape, and may be a cylindrical shape or another polyhedral shape. Sectional shapes of incident end surface 31 and emission end surface 32 are not limited to a rectangle, and may be a circle, an ellipse, or another polygon.

In one modification, the shape of exterior part 4 is not limited to the hexahedral shape, and may be a cylindrical shape or another polyhedral shape. The sectional shapes of first surface 41 and second surface 42 of exterior part 4 are not limited to the rectangle, and may be a circle, an ellipse, or another polygon.

In one modification, exterior part 4 may be configured to convert the wavelength of light L1 incident from first surface 41 into a wavelength different from the wavelength of light L1 emitted from emission end surface 32 and emit light L1 from second surface 42. That is, similarly to optical waveguide 3, exterior part 4 may be a wavelength conversion element using a non-linear optical effect. However, exterior part 4 is set such that a wavelength of light to be emitted is different from optical waveguide 3. This configuration can improve a degree of freedom of a plurality of light rays having different wavelengths (first emission light L21 and second emission light L22) output from light L1 having a single wavelength.

In one modification, the shape of intermediate part 8 is not limited to the hexahedral shape, and may be a cylindrical shape or another polyhedral shape. The sectional shapes of first intermediate surface 81 and second intermediate surface 82 of intermediate part 8 are not limited to the rectangle, and may be a circle, an ellipse, or other polygons. The number of intermediate parts 8 is not particularly limited, and intermediate parts 8 are not essential.

In one modification, intermediate part 8 may not necessarily have a function of converting the wavelength of light L1.

In one modification, waveguide structure 5 is not limited to the optical waveguide SHG element, and may be another waveguide structure.

In one modification, convergence optical system 6 is not limited to the combination of the collimator lens and the condenser lens as described in the first exemplary embodiment. Convergence optical system 6 can include one or more known optical elements.

In one modification, shaping optical system 7 may be configured to change the shapes of the plurality of light rays having different wavelengths emitted from radiation surface 52 of waveguide structure 5. As an example, shaping optical system 7 may be capable of changing at least one of the shape of first emission light L21 and the shape of second emission light L22. In waveguide structure 5E of FIG. 9, shaping optical system 7 may be capable of changing at least one of the shape of first emission light L21, the shape of second emission light L22, and the shape of third emission light L23. Shaping optical system 7 may be configured to change the positional relationship among the plurality of light rays (for example, first emission light L21, second emission light L22, and third emission light L23) having different wavelengths emitted from radiation surface 52 of waveguide structure 5. Shaping optical system 7 is not limited to the configuration of FIG. 7, and can be realized by a combination of one or more optical elements, for example, an aspherical lens, a diffraction grating, and the like.

In one modification, support 10 is not limited to the configuration of support 10 of FIG. 1. In support 10, first attachment member 12 may include a movement mechanism that moves waveguide structure 5 relative to light source 2. Support 10 may not include movement mechanism 131.

### 3. Aspects

As is apparent from the above exemplary embodiment and modification example, the present disclosure includes the following aspects. Hereinafter, reference marks are given in parentheses only to clarify the correspondence with the exemplary embodiment. Note that, the second and subsequent parenthesized reference signs may be omitted in consideration of the legibility of the text.

A first aspect is light-emitting device (1; 1A), and includes light source (2) that emits light (L1) having directionality and having a single wavelength, and waveguide structure (5; 5A to 5J) that includes optical wavelength (3; 3G; 3H) having incident end surface (31) and emission end surface (32), converting a wavelength of light (L1) incident on incident end surface (31), and emitting light (L1) from emission end surface (32), and exterior part (4; 4G; 4H; 4I) having light transparency and covering optical waveguide (3; 3G; 3H) to cause at least incident end surface (31) and emission end surface (32) to be exposed. Exterior part (4; 4G; 4H; 4I) has first surface (41) and second surface (42) opposite to first surface (41). The first surface (41) is closer to light source (2) than the second surface (42) is. Waveguide structure (5; 5E to 5J) has light receiving surface (51) including incident end surface (31) and first surface (41), and radiation surface (52) including emission end surface (32) and second surface (42). A position of waveguide structure (5; 5E to 5J) with respect to light source (2) is determined to cause light (L1) to be incident on light receiving surface (51). Incident range (R) in which light (L1) is incident on light receiving surface (51) includes at least a part of incident end surface (31) and at least a part of first surface (41) such that a part of light (L1) is incident on incident end surface (31) and another part of light (L1) is incident on first surface (41), passes through an inside of exterior part (4; 4G; 4H; 4I), and is emitted from second surface (42). In this aspect, the plurality of light rays (first emission light L21 and second emission light L22) having different wavelengths can be emitted from light (L1) having a single wavelength at desired output ratios and sectional shapes.

A second aspect is light-emitting device (1; 1A to 1F) based on the first aspect. In the second aspect, the exterior part (4; 4G; 4H; 4I) has outer surface (43) opposite to optical waveguide (3; 3G; 3H). Light (L1) is incident on light receiving surface (51) such that light (L1) propagates through the incident of exterior part (4; 4G; 4H; 4I) while being totally reflected by outer surface (43). This aspect can improve utilization efficiency of light (L1).

A third aspect is light-emitting device (1; 1A) based on the first or second aspect. In the third aspect, light-emitting device (1; 1A) further includes convergence optical system (6) that causes light (L1) to be incident on light receiving surface (51) between light source (2) and waveguide structure (5; 5E to 5J). θ satisfies the following expression:

$$θ < 90 ° - arcsin \frac{1}{n} \qquad [ Math . 18 ]$$

where n represents a refractive index of exterior part (4; 4G; 4H; 4I), and θ represents an angle of an outer edge of light (L1) with respect to optical axis (A1) of light (L1) within a predetermined surface passing through optical axis (A1).

This aspect can improve utilization efficiency of light (L1).

A fourth aspect is light-emitting device (1) based on the third aspect. In the fourth aspect, convergence optical system (6) has focal point (F) on a side opposite to light source (2) with respect to light receiving surface (51) of waveguide structure (5; 5E to 5J). Light source (2) has emission surface (2b) from which light (L1) is emitted. a is larger than b, and x satisfies the following expression:

$$0 \leq x < \frac{a - b}{2 \cdot tan θ} \qquad [ Math . 19 ]$$

where x represents a distance between a surface of convergence optical system (6) facing light receiving surface (51) and light receiving surface (51), a represents a width of light (L1) on emission surface (2b) within the predetermined surface, and b represents a width of optical waveguide (3; 3G; 3H) within the predetermined surface.

This aspect can improve utilization efficiency of light (L1).

A fifth aspect is light-emitting device (1A) based on the third aspect. In the fifth aspect, convergence optical system (6) has focal point (F) on the same side as light source (2) with respect to light receiving surface (51) of waveguide structure (5; 5E to 5J). x satisfies the following expression:

$$\frac{b - d}{2 \cdot tan θ} + y < x < \frac{c - d}{2 \cdot tan θ} + y \qquad [ Math . 20 ]$$

where x represents a distance between a surface of convergence optical system (6) facing light receiving surface (51) and light receiving surface (51), y represents a distance between the surface of convergence optical system (6) facing light receiving surface (51) and focal point (F), b represents a width of optical waveguide (3; 3G; 3H) within the predetermined surface, c represents a width of waveguide structure (5; 5E to 5J) within the predetermined surface, and d represents a width of light (L1) at focal point (F) within the predetermined surface.

This aspect can improve utilization efficiency of light (L1).

A sixth aspect is light-emitting device (1B; 1C) based on the first or second aspect. In the sixth aspect, light source (2) has emission surface (2b) from which light (L1) is emitted. Light source (2) and waveguide structure (5; 5E to 5J) are positioned such that light (L1) from light source (2) is directly incident on light receiving surface (51) of waveguide structure (5; 5E to 5J). φ satisfies the following expression:

$$φ < 180 ° - 2 \cdot arcsin \frac{1}{n} \qquad [ Math . 21 ]$$

where n represents a refractive index of exterior part (4; 4G; 4H; 4I), and φ represents a spread angle of a light flux of light (L1) on emission surface (2b) within a predetermined surface passing through optical axis (A1) of light (L1).

This aspect can improve utilization efficiency of light (L1).

A seventh aspect is light-emitting device (1B) based on the sixth aspect. In the seventh aspect, a, b, and c satisfy a relationship of a<b<c. z satisfies the following expression:

$$\frac{b - a}{2 \cdot tan \frac{φ}{2}} < z < \frac{c - a}{2 \cdot tan \frac{φ}{2}} \qquad [ Math . 22 ]$$

where a represents a width of light (L1) on emission surface (2b) within the predetermined surface, b represents a width of optical waveguide (3; 3G; 3H) within the predetermined surface, c represents a width of the waveguide structure (5; 5E to 5J) within the predetermined surface, and z represents a distance between emission surface (2b) and light receiving surface (51).

This aspect can improve utilization efficiency of light (L1).

An eighth aspect is light-emitting device (1C) based on the sixth aspect. In the eighth aspect, a, b, and c satisfy a relationship of b<a<c. z satisfies the following expression:

$$0 \leq z < \frac{c - a}{2 \cdot tan \frac{φ}{2}} \qquad [ Math . 23 ]$$

where a represents a width of light (L1) on emission surface (2b) within the predetermined surface, b represents a width of optical waveguide (3; 3G; 3H) within the predetermined surface, c represents a width of waveguide structure (5; 5E to 5J) within the predetermined surface, and z represents a width of waveguide structure (5; 5E to 5J) within the predetermined surface.

This aspect can improve utilization efficiency of light (L1).

A ninth aspect is light-emitting device (1D) based on any one of the first to eighth aspects. In the ninth aspect, light-emitting device (1D) further includes shaping optical system (7) on which light (L21 and L22) from radiation surface (52) is incident. Shaping optical system (7) changes at least one of a shape of first emission light (L21) emitted from emission end surface (32), a shape of second emission light (L22) emitted from second surface (42), and a positional relationship between first emission light (L21) and second emission light (L22). In this aspect, it is easy to set the shapes of and the positional relationship between the plurality of light rays (first emission light L21 and second emission light L22) having different wavelengths.

A tenth aspect is light-emitting device (1D) based on the ninth aspect. In the tenth aspect, shaping optical system (7) includes at least one of an aspherical lens and a diffraction grating. In this aspect, it is easy to set the shapes of and the positional relationship between the plurality of light rays (first emission light L21 and second emission light L22) having different wavelengths.

An eleventh aspect is light-emitting device (1D) based on the ninth or tenth aspect. In the eleventh aspect, shaping optical system (7) switches between positions of first emission light (L1) and second emission light (L1). In this aspect, it is easy to set the shapes of and the positional relationship between the plurality of light rays (first emission light L21 and second emission light L22) having different wavelengths.

A twelfth aspect is light-emitting device (1; 1A to 1F) based on any one of the first to eleventh aspects. In the twelfth aspect, exterior part (4; 4G; 4H; 4I) is configured to convert a wavelength of light (L1) incident from first surface (41) into a wavelength different from a wavelength of light (L1) emitted from emission end surface (32), and emit light (L1) from second surface (42). This aspect can improve a degree of freedom of a plurality of light rays (first emission light L21 and second emission light L22) having different wavelengths output from light (L1) having a single wavelength.

A thirteenth aspect is light-emitting device (1E) based on any one of the first to twelfth aspects. In the thirteenth aspect, waveguide structure (5E or 5J) further includes one or more intermediate parts (8; 8a, 8b) between optical waveguide (3; 3G; 3H) and exterior part (4; 4G; 4H; 4I). One or more intermediate parts (8; 8a, 8b) have light transparency, and emit light (L1), which is incident on one or more intermediate parts (8; 8a, 8b) from light receiving surface (51) side, from radiation surface (52) side to an outside of one or more intermediate parts (8; 8a, 8b). In this aspect, the plurality of light rays (first emission light L21, second emission light L22, and third emission light L23) having different wavelengths can be emitted from light (L1) having a single wavelength at desired output ratios and sectional shapes.

A fourteenth aspect is light-emitting device (1; 1A to 1F) based on any one of the first to thirteenth aspects. In the fourteenth aspect, light-emitting device (1; 1A to 1F) includes movement mechanism (131) that moves waveguide structure (5; 5E to 5J) relative to light source (2). In this aspect, it is easy to set a positional relationship between waveguide structure (5; 5E to 5J) and light source (2).

A fifteenth aspect is light-emitting device (1; 1A to 1F) based on any one of the first to fourteenth aspects. In the fifteenth aspect, one of light (first emission light L21) emitted from emission end surface (32) and light (second emission light L22) emitted from second surface (42) is visible light. The other of the light (first emission light L21) emitted from the emission end surface (32) and the light (second emission light L22) emitted from second surface (42) is invisible light. Since this aspect can be used by combining visible light and invisible light, usability of the light-emitting device can be improved.

A sixteenth aspect is light-emitting device (1; 1A to 1F) based on any one of the first to fifteenth aspects. In the sixteenth aspect, incident end surface (31) and first surface (41) are present on an identical plane on light receiving surface (51). This aspect can improve utilization efficiency of light (L1).

According to the aspects of the present disclosure, the plurality of light rays having different wavelengths from light having a single wavelength can be emitted at desired output ratios and sectional shapes.

### INDUSTRIAL APPLICABILITY

The present disclosure is applicable to light-emitting devices. Specifically, the present disclosure is applicable to a light-emitting device including a light source that emits light having directionality and having a single wavelength. In addition, the present disclosure is also applicable to an irradiation device that emits an electromagnetic wave having directionality. In addition, the present disclosure can be used for application of irradiation with light rays having a plurality of wavelengths in various fields such as a machining field, an optical information processing field, and an optical application measurement control field.

### REFERENCE MARKS IN THE DRAWINGS

1, 1A, 1B, 1C, 1D, 1E, 1F: light-emitting device
2: light source
2b: emission surface
3, 3G, 3H: optical waveguide
31: incident end surface
32: emission end surface
4, 4G, 4H, 4I: exterior part
41: first surface
42: second surface
43: outer surface
5, 5E, 5F,5G,5H,5I,5J: waveguide structure
51: light receiving surface
52: radiation surface
6: convergence optical system
7: shaping optical system
8, 8a, 8b: intermediate part
131: movement mechanism
L1: light
A1: optical axis
L21: first emission light (light)
L22: second emission light (light)
L23: third emission light (light)
F: focal point

1. A light-emitting device comprising:
a light source that emits light having directionality and having a single wavelength; and
a guide structure that includes an optical waveguide and an exterior part, the optical waveguide having an incident end surface and an emission end surface, converting a wavelength of light incident on the incident end surface, and emitting the light from the emission end surface, and the exterior part having light transparency and covering the optical waveguide to cause at least the incident end surface and the emission end surface to be exposed,
wherein the exterior part has a first surface and a second surface opposite to the first surface, the first surface being closer to the light source than the second surface is,
the waveguide structure includes:
a light receiving surface including the incident end surface and the first surface; and
a radiation surface including the emission end surface and the second surface,
a position of the waveguide structure with respect to the light source is determined to cause the light to be incident on the light receiving surface, and
an incident range in which the light is incident on the light receiving surface includes at least a part of the incident end surface and at least a part of the first surface, a part of the light being incident on the incident end surface, and another part of the light being incident on the first surface, passing through an inside of the exterior part, and being emitted from the second surface.

2. The light-emitting device according to claim 1, wherein
the exterior part has an outer surface opposite to the optical waveguide, and
the light is incident on the light receiving surface, the light propagating the inside of the exterior part while being totally reflected by the outer surface.

3. The light-emitting device according to claim 1, further comprising
a convergence optical system that causes the light to be incident on the light receiving surface between the light source and the waveguide structure,
wherein, θ satisfies the following expression:
$$θ < 90 ° - arcsin \frac{1}{n} \qquad [ Math . 1 ]$$
where n represents a refractive index of the exterior part, and θ represents an angle of an outer edge of the light with respect to an optical axis of the light within a predetermined surface passing through the optical axis.

4. The light-emitting device according to claim 3, wherein
the convergence optical system has a focal point on a side opposite to the light source with respect to the light receiving surface of the waveguide structure,
the light source has an emission surface from which the light is emitted, and
a is larger than b, and x satisfies the following expression:
$$0 \leq x < \frac{a - b}{2 \cdot tan θ} \qquad [ Math . 2 ]$$
where x represents a distance between a surface of the convergence optical system facing the light receiving surface and the light receiving surface, a represents a width of the light on the emission surface within the predetermined surface, and b represents a width of the optical waveguide within the predetermined surface.

5. The light-emitting device according to claim 3, wherein
the convergence optical system has a focal point on a same side as the light source with respect to a light receiving surface of the waveguide structure, and
x satisfies the following expression:
$$\frac{b - d}{2 \cdot tan θ} + y < x < \frac{c - d}{2 \cdot tan θ} + y \qquad [ Math . 3 ]$$
where x represents a distance between a surface of the convergence optical system facing the light receiving surface and the light receiving surface, y represents a distance between the surface of the convergence optical system facing the light receiving surface and the focal point, b represents a width of the optical waveguide within the predetermined surface, c represents a width of the waveguide structure within the predetermined surface, and d represents a width of the light at the focal point within the predetermined surface.

6. The light-emitting device according to claim 1, wherein
the light source has an emission surface from which the light is emitted,
the light source and the waveguide structure are positioned, the light from the light source being directly incident on the light receiving surface of the waveguide structure, and
φ satisfies the following expression:
$$φ < 180 ° - 2 \cdot arcsin \frac{1}{n} \qquad [ Math . 4 ]$$
where n represents a refractive index of the exterior part, φ represents a spread angle of a light flux of the light on the emission surface within a predetermined surface passing through an optical axis of the light.

7. The light-emitting device according to claim 6, wherein
a, b, and c satisfy a relationship of a<b<c, and
z satisfies the following expression:
$$\frac{b - a}{2 \cdot tan \frac{φ}{2}} < z < \frac{c - a}{2 \cdot tan \frac{φ}{2}} \qquad [ Math . 5 ]$$
where a represents a width of the light on the emission surface within the predetermined surface, b represents a width of the optical waveguide within the predetermined surface, c represents a width of the waveguide structure within the predetermined surface, and z represents a distance between the emission surface and the light receiving surface.

8. The light-emitting device according to claim 6, wherein
a, b, and c satisfy a relationship of b<a<c, and
z satisfies the following expression:
$$0 \leq z < \frac{c - a}{2 \cdot tan \frac{φ}{2}} \qquad [ Math . 6 ]$$
where a represents a width of the light on the emission surface within the predetermined surface, b represents a width of the optical waveguide within the predetermined surface, c represents a width of the waveguide structure within the predetermined surface, and z represents a distance between the emission surface and the light receiving surface.

9. The light-emitting device according to claim 1, further comprising
a shaping optical system on which light from the radiation surface is incident,
wherein the shaping optical system changes at least one of a shape of first emission light emitted from the emission end surface, a shape of second emission light emitted from the second surface, and a positional relationship between the first emission light and the second emission light.

10. The light-emitting device according to claim 9, wherein the shaping optical system includes at least one of an aspherical lens and a diffraction grating.

11. The light-emitting device according to claim 9, wherein the shaping optical system switches positions of the first emission light and the second emission light.

12. The light-emitting device according to claim 1, wherein the exterior part is configured to convert a wavelength of light incident from the first surface into a wavelength different from a wavelength of light emitted from the emission end surface, and emit the light from the second surface.

13. The light-emitting device according to claim 1, wherein
the waveguide structure further includes one or more intermediate parts between the optical waveguide and the exterior part, and
the one or more intermediate parts have light transparency, and emit light, which is incident on the one or more intermediate parts from the light receiving surface side, from the radiation surface side to an outside of the one or more intermediate parts.

14. The light-emitting device according to claim 1, further comprising
a movement mechanism that moves the waveguide structure relative to the light source.

15. The light-emitting device according to claim 1, wherein
one of light emitted from the emission end surface and light emitted from the second surface is visible light, and
the other of the light emitted from the emission end surface and the light emitted from the second surface is invisible light.

16. The light-emitting device according to claim 1, wherein the incident end surface and the first surface are present on an identical plane on the light receiving surface.
